(19) United States
(12) Patent Application Publication
(10) Pub. No.: US 2025/0392337 A1
(43) Pub. Date: Dec. 25, 2025

(54) TRACKER MODULE, HIGH FREQUENCY SYSTEM, AND COMMUNICATION DEVICE

(71) Applicant: Murata Manufacturing Co., Ltd., Nagaokakyo-shi (JP)

(72) Inventors: Sho OKAMOTO, Nagaokakyo-shi (JP); Muneharu KATO, Nagaokakyo-shi (JP); Kouji YAMAGUCHI, Nagaokakyo-shi (JP)

(21) Appl. No.: 19/310,198

(22) Filed: Aug. 26, 2025

Related U.S. Application Data
(63) Continuation of application No. PCT/JP2024/007333, filed on Feb. 28, 2024.

(30) Foreign Application Priority Data
Mar. 14, 2023 (JP) 2023-040162

(51) Int. Cl. H04B 1/3827; H04B 1/16

(52) U.S. Cl. CPC H04B 1/3827; H04B 1/1615

(57) ABSTRACT

A tracker module is provided with a reduced size. The exemplary tracker module includes a module laminate, an IC chip, and a filter circuit. The IC chip is disposed on the module laminate. The IC chip includes at least one switch included in a supply modulator. The filter circuit includes variable reactance elements whose reactance is varied. The variable reactance elements include at least one reactance element and at least one switch. The at least one switch of the variable reactance elements in the filter circuit is integrated in the IC chip.

### CROSS REFERENCE TO RELATED APPLICATIONS

This application is a continuation of International Application No. PCT/JP2024/007333, filed Feb. 28, 2024, which claims priority to Japanese Patent Application No. Application No. 2023-040162, filed Mar. 14, 2023, the contents of each of which are hereby incorporated by reference in their entireties.

### TECHNICAL FIELD

The present disclosure generally relates to a tracker module, a high frequency system, and a communication device, and more particularly relates to a tracker module including a filter circuit, a high frequency system including a tracker module, and a communication device including a high frequency system.

### BACKGROUND

In recent years, the power added efficiency (PAE) has been improved by applying envelope tracking (ET) to power amplifier (PA) circuits.

For example, U.S. Pat. No. 8,829,993 discloses a voltage control unit that supplies a power supply voltage to a bias terminal of a power amplifier. The voltage control unit disclosed therein includes a multilevel power converter that provides a plurality of discrete voltage levels, a switch circuit (supply modulator), and a transition shaping filter (filter circuit). The switch circuit has a plurality of switches. The transition shaping filter is provided between the switch circuit and the bias terminal of the power amplifier.

However, in a case where a configuration of a voltage control unit disclosed in U.S. Pat. No. 8,829,993 is modularized, the voltage control unit may become large in size.

### SUMMARY OF THE INVENTION

In view of the foregoing, the exemplary aspects of the present disclosure provide a tracker module, a high frequency system, and a communication device that enables size reduction.

In an exemplary aspect, a tracker module is provided that includes, a module laminate, an IC chip, and a filter circuit. The IC chip is disposed on the module laminate and includes at least one switch included in a supply modulator. The supply modulator is configured to selectively output, to a power amplifier, at least one discrete voltage of a plurality of discrete voltages generated based on an input voltage with the filter circuit interposed therebetween. The filter circuit includes variable reactance elements. The variable reactance elements include at least one reactance element, which can be a capacitor or an inductor, and at least one switch. The at least one switch of the variable reactance elements in the filter circuit is integrated in the IC chip.

In another exemplary aspect, a tracker module is provide that includes a module laminate, an IC chip, and a filter circuit. The IC chip is disposed on the module laminate. The IC chip includes at least one switch included in a switched-capacitor circuit and at least one switch included in a supply modulator. The switched-capacitor circuit includes a first capacitor having a first electrode and a second electrode, and a second capacitor having a third electrode and a fourth electrode. The at least one switch included in the switched-capacitor circuit includes a first switch, a second switch, a third switch, a fourth switch, a fifth switch, a sixth switch, a seventh switch, and an eighth switch. A first end of the first switch and a first end of the third switch are connected to the first electrode of the first capacitor. A first end of the second switch and a first end of the fourth switch are connected to the second electrode of the first capacitor. A first end of the fifth switch and a first end of the seventh switch are connected to the third electrode of the second capacitor. A first end of the sixth switch and a first end of the eighth switch are connected to the fourth electrode of the second capacitor. A second end of the first switch, a second end of the second switch, a second end of the fifth switch, and a second end of the sixth switch are connected to each other. A second end of the third switch is connected to a second end of the seventh switch. A second end of the fourth switch is connected to a second end of the eighth switch. The at least one switch included in the supply modulator includes a ninth switch which is connected between the second end of the first switch, the second end of the second switch, the second end of the fifth switch, the second end of the sixth switch, and the filter circuit; and a tenth switch which is connected between the second end of the third switch, the second end of the seventh switch, and the filter circuit. The filter circuit includes a variable reactance elements. The variable reactance elements include at least one reactance element, which can be a capacitor or an inductor, and at least one switch corresponding to the at least one reactance element. The at least one reactance element includes a first reactance element; and a second reactance element which is connected in parallel to the first reactance element. The at least one switch of the filter circuit includes an eleventh switch which is connected in series to the first reactance element, and; a twelfth switch which is connected in parallel to the eleventh switch and is connected in series to the second reactance element. The at least one switch of the variable reactance elements in the filter circuit is integrated in the IC chip.

In another exemplary aspect, a high frequency system is provided that includes the tracker module and a power amplifier. The power amplifier is connected to the tracker module.

In another exemplary aspect, a communication device is provided that includes the high frequency system and a signal processing circuit. The signal processing circuit is connected to the high frequency system.

According to the tracker module, size reduction can be achieved by the high frequency system, and the communication device according to the above-described exemplary aspects.

### BRIEF DESCRIPTION OF DRAWINGS

FIG. 1 is a conceptual diagram of a tracker module according to Exemplary Embodiment 1.

FIG. 2 is a plan view of the tracker module according to Exemplary Embodiment 1.

FIG. 3 illustrates the tracker module according to Exemplary Embodiment 1 and is a cross-sectional view taken along line III-III in FIG. 2.

FIG. 4 is a circuit block diagram of a power supply circuit, a high frequency system, and a communication device according to Exemplary Embodiment 1.

FIG. 5A is a waveform diagram illustrating one example of a transition of a power supply voltage in a digital ET mode. FIG. 5B is waveform diagram illustrating one example of a transition of a power supply voltage in an analog ET mode.

FIG. 6 is a circuit diagram of the power supply circuit according to Exemplary Embodiment 1.

FIG. 7 is a circuit configuration diagram of a digital control circuit in the power supply circuit of the above embodiment.

FIG. 8 is a conceptual diagram of a tracker module according to a modification example of Exemplary Embodiment 1.

FIG. 9 is a conceptual diagram of a tracker module according to Exemplary Embodiment 2.

FIG. 10 is a conceptual diagram of a tracker module according to a modification example of Exemplary Embodiment 2.

FIG. 11 is a conceptual diagram of a tracker module according to Exemplary Embodiment 3.

FIG. 12 is a conceptual diagram of a tracker module according to a modification example of Exemplary Embodiment 3.

FIG. 13 is a conceptual diagram of a tracker module according to Exemplary Embodiment 4.

FIG. 14 is a conceptual diagram of a tracker module according to a modification example of Exemplary Embodiment 4.

FIG. 15 is a conceptual diagram of a tracker module according to Exemplary Embodiment 5.

FIG. 16 is a plan view of the tracker module of the above embodiment.

FIG. 17 is a conceptual diagram of a tracker module according to a modification example of Exemplary Embodiment 5.

FIG. 18 is a conceptual diagram of a tracker module according to Exemplary Embodiment 6.

FIG. 19 is a conceptual diagram of a tracker module according to a modification example of Exemplary Embodiment 6.

FIG. 20 is a conceptual diagram of a tracker module according to Exemplary Embodiment 7.

FIG. 21 is a conceptual diagram of a tracker module according to a modification example of Exemplary Embodiment 7.

FIG. 22 is a conceptual diagram of a tracker module according to Exemplary Embodiment 8.

FIG. 23 is a conceptual diagram of a tracker module according to a modification example of Exemplary Embodiment 8.

FIG. 24 is a conceptual diagram of a tracker module according to Exemplary Embodiment 9.

FIG. 25 is a conceptual diagram of a tracker module according to a modification example of Exemplary Embodiment 9.

### DETAILED DESCRIPTION OF EMBODIMENTS

In the following, Exemplary Embodiments 1 to 9 will be described with reference to the drawings. The figures referred to in the following embodiments and the like are schematic diagrams. Sizes and thicknesses of components in the figures do not necessarily reflect actual dimensions, and size ratios and thickness ratios between the components do not necessarily reflect actual dimensional ratios.

### Exemplary Embodiment 1

### Tracker Module

A tracker module 100 according to Exemplary Embodiment 1 will be described with reference to the drawings.

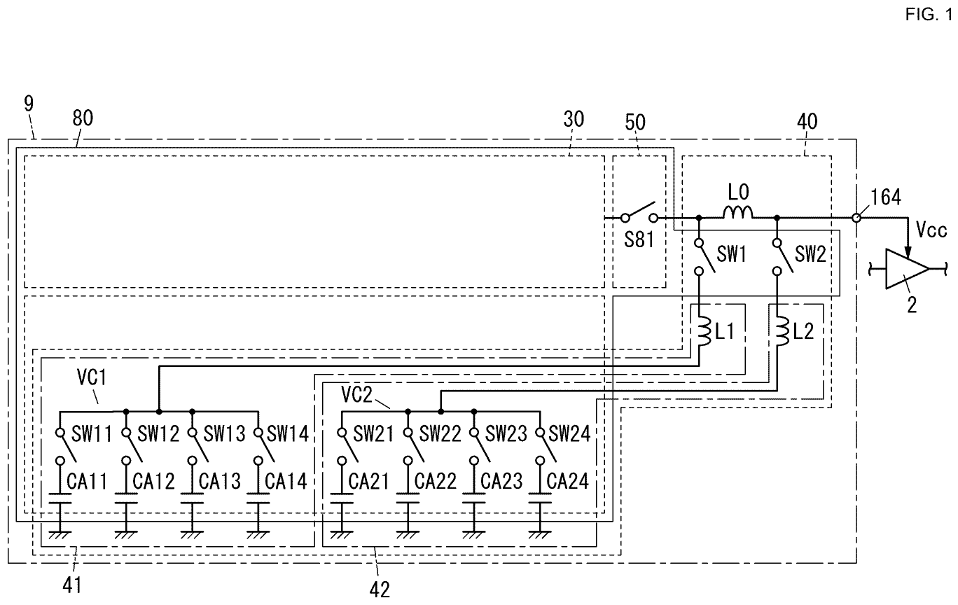

As illustrated in FIGS. 1 to 3, the tracker module 100 according to Exemplary Embodiment 1 includes a module laminate 9, an IC chip 80, and a filter circuit 40. The IC chip 80 is disposed on the module laminate 9. The IC chip 80 includes at least one of switches S51 to S54 included in a supply modulator 30. The supply modulator 30 is configured to selectively output, to a power amplifier 2, at least one of a plurality of discrete voltages generated based on an input voltage with the filter circuit 40 interposed therebetween. The filter circuit 40 includes a variable capacitor VC1 (e.g., a variable reactance element) whose reactance is variable. The variable capacitor VC1 and a variable capacitor VC2 include a plurality of capacitors CA11 to CA14 and CA21 to CA24, and a plurality of switches SW11 to SW14 and SW21 to SW24. The plurality of switches SW11 to SW14 and SW21 to SW24 are integrated in the IC chip 80.

In the present disclosure, a reactance element is an element having reactance components (e.g., capacitance and inductance), and is a capacitor or an inductor.

In the present disclosure, a variable reactance element refers to an element whose reactance is varied by at least one reactance element. The variable reactance element may include only a single reactance element whose reactance is variable or may include a plurality of reactance elements having mutually different reactance.

### (2) Circuit Configurations of Power Supply Circuit, High Frequency System, and Communication Device

In the following, circuit configurations of a power supply circuit 1, a high frequency system 200, and a communication device 7 according to Exemplary Embodiment 1 will be described with reference to the drawings.

### (2.1) Circuit Configuration of High Frequency System

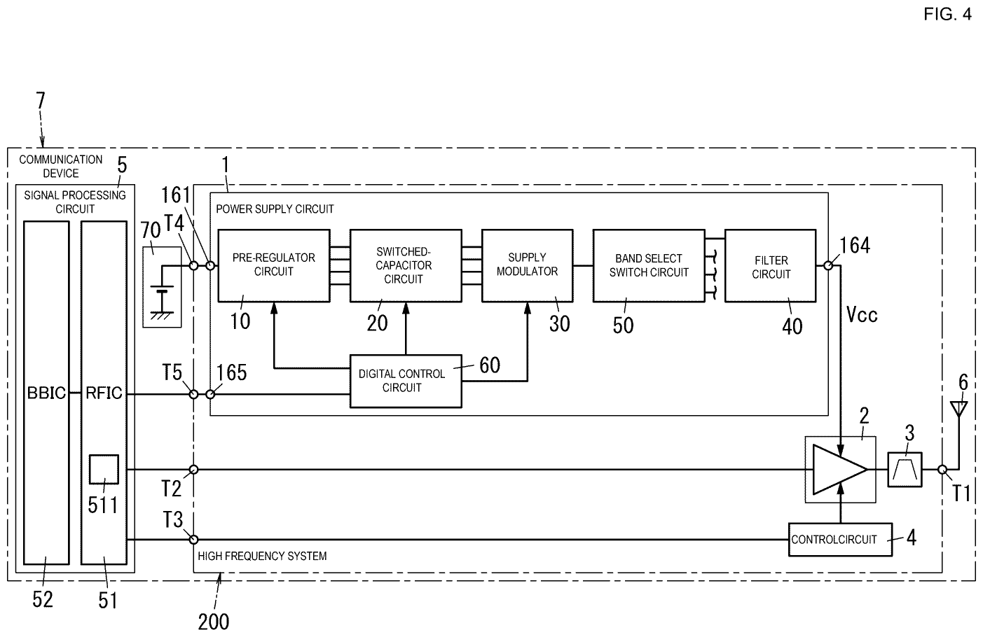

As illustrated in FIG. 4, the high frequency system 200 includes the power supply circuit 1, the power amplifier 2, a filter 3, a control circuit 4, and a plurality of external connection terminals. The plurality of external connection terminals includes an antenna terminal T1, a signal input terminal T2, a first control terminal T3, a power supply connection terminal T4, and four second control terminals T5 (only one of which is illustrated in FIG. 4).

The power supply circuit 1 is a circuit that supplies, to the power amplifier 2, a power supply voltage Vcc having a voltage level selected from a plurality of discrete voltages, based on an envelope signal.

In the communication device 7 that includes the power supply circuit 1 and the power amplifier 2, an envelope tracking method (hereinafter referred to as an “ET method”) is used when a radio frequency signal is amplified in the power amplifier 2. The ET method includes an analog-envelope-tracking method (hereinafter referred to as an “analog ET method”) and a digital-envelope-tracking method (hereinafter referred to as a “digital ET method”).

The digital ET method is a method of tracking an envelope of a radio frequency signal (e.g., a modulated signal) using a plurality of discrete voltages with different voltage levels within one frame. A mode in which the digital ET method is applied to generation of a power supply voltage VCC is referred to as a digital ET mode. In addition, the analog ET method is a method of tracking an envelope of a radio frequency signal using continuous voltage levels. A mode in which the analog ET method is used to generate a power supply voltage Vcc is referred to as an analog ET mode.

For purposes of this disclosure, a frame represents a unit that forms a radio frequency signal. For example, in 5G NR (5th Generation New Radio) and an LTE® (Long Term Evolution), a frame contains 10 subframes, each subframe including a plurality of slots, and each slot including a plurality of symbols. A subframe has a length of 1 millisecond (ms), and a frame has a length of 10 ms.

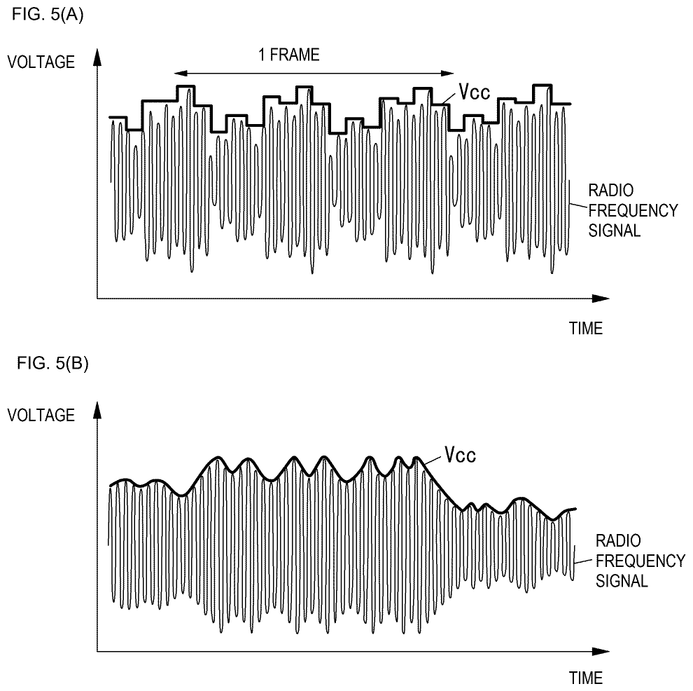

Here, the digital ET mode and the analog ET mode will be described with reference to FIGS. 5A and 5B.

In the digital ET mode, as illustrated in FIG. 5A, an envelope of a radio frequency signal is tracked by fluctuating the power supply voltage Vcc to a plurality of discrete voltage levels within one frame. As a result, a waveform of the power supply voltage Vcc becomes a waveform like a rectangular wave. In the digital ET mode, based on the envelope signal, a power supply voltage level is selected from the plurality of discrete voltage levels.

In the analog ET mode, as illustrated in FIG. 5B, the envelope of the modulated signal is tracked by continuously fluctuating the power supply voltage Vcc. In the analog ET mode, when a channel band width is narrow (when the channel band width is less than 60 MHz, for example), the power supply voltage Vcc easily follows changes in the envelope of the radio frequency signal. However, when the channel band width is wide (when the channel band width is 60 MHz or higher, for example), the power supply voltage Vcc finds it difficult to follow changes in the envelope of the radio frequency signal. In other words, when the channel band width is wide, amplitude changes of the power supply voltage Vcc easily lag behind the changes in the envelope of the radio frequency signal.

In contrast, when the channel band width is wide, application of the digital ET mode can improve an ability of the power supply voltage Vcc to follow the radio frequency signals.

As illustrated in FIG. 4, the power supply circuit 1 includes a pre-regulator circuit 10, a switched-capacitor circuit 20, a supply modulator 30, and a filter circuit 40.

The pre-regulator circuit 10 is, for example, a DC (Direct Current)/DC converter that converts a direct-current voltage (first voltage) supplied from a direct current (DC) power source 70 included in the communication device 7 into a second voltage. The pre-regulator circuit 10 is configured to perform a step-up operation to make a voltage value of the first voltage larger than a voltage value of the second voltage, and a step-down operation to make the voltage value of the second voltage smaller than the voltage value of the first voltage. That is, the pre-regulator circuit 10 is a step-up/step-down type DC-DC converter.

The switched-capacitor circuit 20 is configured to generate a plurality of discrete voltages (a plurality of third voltages) using the second voltage from the pre-regulator circuit 10 as its input voltage. The plurality of discrete voltages has mutually different voltage levels. The switched-capacitor circuit 20 may be referred to as a switched-capacitor voltage balancer (Switched-Capacitor Voltage Balancer).

The supply modulator 30 is configured to selectively output, to the filter circuit 40, at least one of the plurality of discrete voltages (the plurality of third voltages) generated at the switched-capacitor circuit 20, based on a digital control signal corresponding to the envelope signal. The supply modulator 30 outputs at least one discrete voltage selected from the plurality of discrete voltages. In the power supply circuit 1, selection of the discrete voltages at the supply modulator 30 is repeated over time, so that the voltage level of an output voltage (power supply voltage Vcc) of the supply modulator 30 can be varied over time. This configuration enables the power supply circuit 1 to vary the voltage level of the power supply voltage Vcc supplied to the power amplifier 2 over time.

The filter circuit 40 filters the output voltage of the supply modulator 30. The filter circuit 40 includes a low pass filter, for example. The filter circuit 40 reduces an amplitude of a spike-like voltage in the output voltage output from the supply modulator 30. That is, by including the filter circuit 40, the power supply circuit 1 can reduce waveform distortion of the output voltage output from the supply modulator 30, and thus can reduce radio frequency components in the output voltage. This configuration reduces noise contained in the power supply voltage Vcc in the power supply circuit 1, so that noise entering the power amplifier 2 from the power supply circuit 1 is also reduced.

The power amplifier 2 has an input terminal, an output terminal, a power supply terminal, and a control terminal. The input terminal of the power amplifier 2 is connected to the signal processing circuit 5 of the communication device 7 with the signal input terminal T2 interposed therebetween. The output terminal of the power amplifier 2 is connected to an antenna 6 of the communication device 7 with the filter 3 and the antenna terminal T1 interposed therebetween. The power amplifier 2 amplifies and outputs a radio frequency transmission signal (hereinafter referred to as a “transmission signal”) of a predetermined band that is output from the signal processing circuit 5.

The filter 3 is connected between the output terminal of the power amplifier 2 and the antenna terminal T1. The filter 3 has a passband that includes a predetermined frequency band. This configuration enables the filter 3 to pass the transmission signal of the predetermined band amplified by the power amplifier 2. In the high frequency system 200, a transmission signal output from the power amplifier 2 is output to the antenna 6 with the filter 3 and the antenna terminal T1 interposed therebetween.

The control circuit 4 is connected to an RF signal processing circuit 51 of the signal processing circuit 5 with the first control terminal T3 interposed therebetween. In addition, the control circuit 4 is connected to the control terminal of the power amplifier 2. The control circuit 4 controls magnitude and supply timing of a bias current (or a bias voltage) supplied to the control terminal of the power amplifier 2, by receiving a control signal from the RF signal processing circuit 51 of the signal processing circuit 5.

### (2.2) Circuit Configuration of Communication Device

As illustrated in FIG. 4, the communication device 7 includes the high frequency system 200, the signal processing circuit 5, the antenna 6, and the direct current power source 70.

The direct current power source 70 is a rechargeable battery (e.g., a rechargeable battery), for example. For purposes of this disclosure, it is noted that the direct current power source 70 is not limited to a rechargeable battery, but may be another battery in an exemplary aspect.

The antenna 6 transmits a transmission signal of a predetermined band output from the antenna terminal T1.

The signal processing circuit 5 includes the RF signal processing circuit 51 and a baseband signal processing circuit 52. The RF signal processing circuit 51 is, for example, an RFIC (Radio Frequency Integrated Circuit), and performs signal processing on radio frequency signals. The RF signal processing circuit 51 performs, for example, signal processing such as up-conversion, and the like, on radio frequency signals (e.g., transmission signals) output from the baseband signal processing circuit 52, and outputs the radio frequency signals subjected to the signal processing. The baseband signal processing circuit 52 is a BBIC (Baseband Integrated Circuit), for example. The baseband signal processing circuit 52 generates an I-phase signal and a Q-phase signal from a baseband signal. The baseband signal is an audio signal or an image signal input from outside. The baseband signal processing circuit 52 performs IQ modulation processing by synthesizing the I-phase signal and the Q-phase signal and outputs a transmission signal. At this time, the transmission signal is generated as a modulation signal (e.g., an IQ signal) in which a carrier signal having a predetermined frequency is amplitude-modulated with a period longer than a period of the carrier signal.

In addition, the RF signal processing circuit 51 includes a control unit 511 that controls the power supply circuit 1 and the power amplifier 2. The control unit 511 of the RF signal processing circuit 51 causes the supply modulator 30 to select a voltage level of the power supply voltage Vcc used in the power amplifier 2, from among the plurality of discrete voltages generated by the switched-capacitor circuit 20 based on the envelope signal of the radio frequency input signal input from the baseband signal processing circuit 52. As a result, the power supply circuit 1 outputs the power supply voltage Vcc based on the digital-envelope-tracking. The envelope signal is a signal indicating the envelope of the radio frequency signal (modulated signal). An envelope value is (I2+Q2) ½, for example. Here, (I, Q) represents a constellation point. The constellation point is a point that represents a signal modulated by digital modulation on a constellation diagram. (I, Q) is determined by the baseband signal processing circuit 52 based on, for example, transmission information. For purposes of this disclosure, it is noted that some or all of functions as the control unit 511 of the RF signal processing circuit 51 may be outside the RF signal processing circuit 51, and the baseband signal processing circuit 52 or the power supply circuit 1 may include some or all of functions as the control unit 511 of the RF signal processing circuit 51. For example, a control function for causing the above supply modulator 30 to select a voltage level of the power supply voltage Vcc may be included in the power supply circuit 1, and not in the RF signal processing circuit 51.

### (2.3) Power Supply Circuit

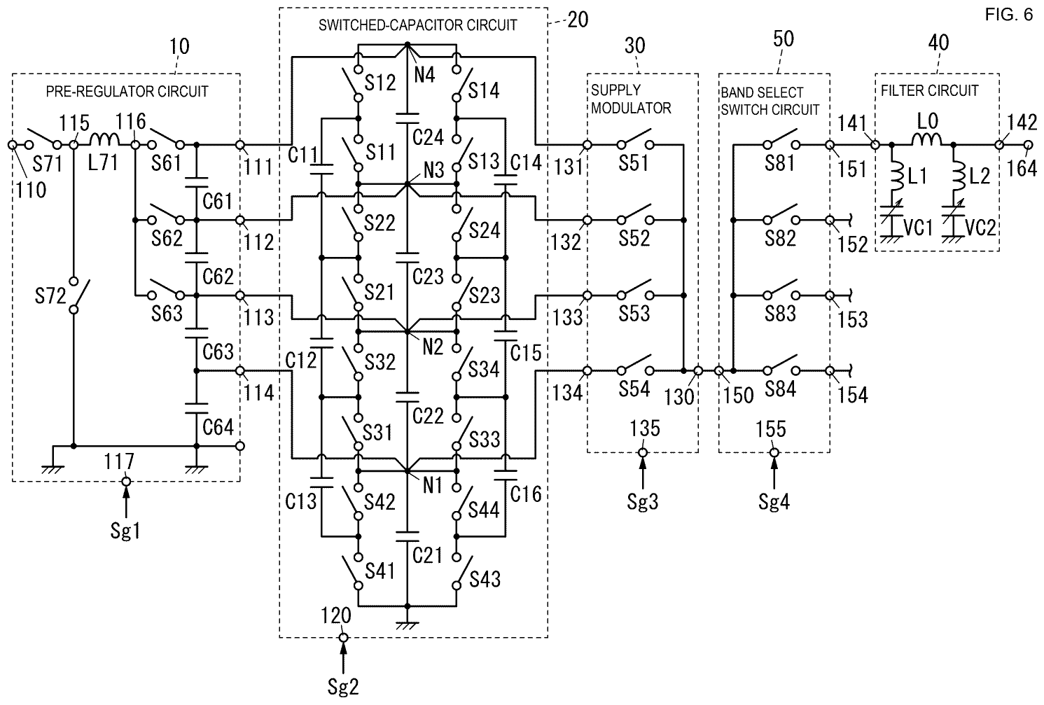

As illustrated in FIG. 6, the power supply circuit 1 includes the pre-regulator circuit 10, the switched-capacitor circuit 20, the supply modulator 30, the filter circuit 40, a band select switch circuit 50, and a digital control circuit 60.

### (2.4) Pre-Regulator Circuit

As illustrated in FIG. 6, the pre-regulator circuit 10 includes an input terminal 110, a plurality of (four in the example of FIG. 6) output terminals 111 to 114, a plurality of inductor connection terminals 115 and 116, a control terminal 117, a plurality of (five in the example of FIG. 6) switches S61, S62, S63, S71, and S72, a power inductor L71, and a plurality of (four in the example of FIG. 6) capacitors C61, C62, C63, and C64. The power inductor L71 is an inductor used to step up and/or step down (step up, step down, or step up/step down) a direct current voltage.

The input terminal 110 is an input terminal for a direct current voltage. That is, the input terminal 110 is a terminal for receiving an input voltage from the direct current power source 70 (see, e.g., FIG. 4).

The output terminal 111 is an output terminal for a voltage V4. That is, the output terminal 111 is a terminal for supplying the voltage V4 to the switched-capacitor circuit 20. The output terminal 111 is connected to a node N4 of the switched-capacitor circuit 20.

The output terminal 112 is an output terminal for a voltage V3. That is, the output terminal 112 is a terminal for supplying the voltage V3 to the switched-capacitor circuit 20. The output terminal 112 is connected to a node N3 of the switched-capacitor circuit 20.

The output terminal 113 is an output terminal for a voltage V2. That is, the output terminal 113 is a terminal for supplying the voltage V2 to the switched-capacitor circuit 20. The output terminal 113 is connected to a node N2 of the switched-capacitor circuit 20.

The output terminal 114 is an output terminal for a voltage V1. That is, the output terminal 114 is a terminal for supplying the voltage V1 to the switched-capacitor circuit 20. The output terminal 114 is connected to a node N1 of the switched-capacitor circuit 20.

The inductor connection terminal 115 is connected to one end (first end) of the power inductor L71. The inductor connection terminal 116 is connected to another end (second end) of the power inductor L71.

The control terminal 117 is an input terminal for a control signal Sg1. That is, the control terminal 117 is a terminal for receiving the control signal Sg1 for controlling the pre-regulator circuit 10. The control signal Sg1 is a signal for controlling ON/OFF of the plurality of switches S61 to S63, S71, and S72 included in the pre-regulator circuit 10.

The switch S71 is connected between the input terminal 110 and the one end (first end) of the power inductor L71. Specifically, the switch S71 has a first terminal connected to the input terminal 110 and a second terminal connected to the one end (first end) of the power inductor L71 with the inductor connection terminal 115 interposed therebetween. In the above connection configuration, the switch S71 switches connection and non-connection between the input terminal 110 and the one end of the power inductor L71 by switching ON/OFF.

The switch S72 is connected between the one end (first end) of the power inductor L71 and ground. Specifically, the switch S72 has a first terminal connected to the one end (first end) of the power inductor L71 with the inductor connection terminal 115 interposed therebetween, and a second terminal connected to ground. In the above connection configuration, the switch S72 switches connection and non-connection between the one end of the power inductor L71 and ground by switching ON/OFF.

The switch S61 is connected between the other end (second end) of the power inductor L71 and the output terminal 111. Specifically, the switch S61 has a first terminal connected to the other end (second end) of the power inductor L71 and a second terminal connected to the output terminal 111. In the above connection configuration, the switch S61 switches connection and non-connection between the other end of the power inductor L71 and the output terminal 111 by switching ON/OFF.

The switch S62 is connected between the other end (second end) of the power inductor L71 and the output terminal 112. Specifically, the switch S62 has a first terminal connected to the other end (second end) of the power inductor L71 and a second terminal connected to the output terminal 112. In the above connection configuration, the switch S62 switches connection and non-connection between the other end of the power inductor L71 and the output terminal 112 by switching ON/OFF.

The switch S63 is connected between the other end (second end) of the power inductor L71 and the output terminal 113. Specifically, the switch S63 has a first terminal connected to the other end (second end) of the power inductor L71 and a second terminal connected to the output terminal 113. In the above connection configuration, the switch S63 switches connection and non-connection between the other end of the power inductor L71 and the output terminal 113 by switching ON/OFF.

The capacitor C61 is connected between the output terminal 111 and the output terminal 112. One of two electrodes of the capacitor C61 is connected to the switch S61 and the output terminal 111, and the other of the two electrodes of the capacitor C61 is connected to the switch S62, the output terminal 112, and one of two electrodes of the capacitor C62.

The capacitor C62 is connected between the output terminal 112 and the output terminal 113. The one of the two electrodes of the capacitor C62 is connected to the switch S62, the output terminal 112, and the other of the two electrodes of the capacitor C61. The other of the two electrodes of the capacitor C62 is connected to the switch S63, the output terminal 113, and one of two electrodes of the capacitor C63.

The capacitor C63 is connected between the output terminal 113 and the output terminal 114. The one of the two electrodes of the capacitor C63 is connected to the switch S63, the output terminal 113, and the other of the two electrodes of the capacitor c62. The other of the two electrodes of the capacitor C63 is connected to the output terminal 114 and one of two electrodes of the capacitor C64.

The capacitor C64 is connected between the output terminal 114 and ground.

The one of the two electrodes of the capacitor C64 is connected to the output terminal 114 and the other of the two electrodes of the capacitor C63, and the other of the two electrodes of the capacitor C64 is connected to the ground.

The plurality of switches S61 to S63 is controlled to be exclusively ON. That is, only any of the switches S61 to S63 is turned ON and the remaining switches S61 to S63 are turned OFF. It becomes possible to vary voltage levels of the voltages V1 to V4 depending on which of the switches S61 to S63 is turned ON.

The pre-regulator circuit 10 configured as described above supplies electric charges to the switched-capacitor circuit 20 through at least one of the plurality of output terminals 111 to 113.

### (2.5) Switched-capacitor Circuit

As illustrated in FIG. 6, the switched-capacitor circuit 20 includes a plurality of (six in the example of FIG. 6) capacitors C11 to C16, a plurality of (four in the example of FIG. 6) capacitors C21 to C24, a plurality of (16 in the example of FIG. 6) switches S11 to S14, S21 to S24, S31 to S34, and S41 to S44, and a control terminal 120.

The control terminal 120 is an input terminal of a control signal Sg2 from the digital control circuit 60. The control signal Sg2 is a signal for controlling ON/OFF of the plurality of switches S11 to S14, S21 to S24, S31 to S34, and S41 to S44 included in the switched-capacitor circuit 20.

Each of the plurality of capacitors C11 to C16 can be configured to function as a flying capacitor (e.g., a transfer capacitor) in an exemplary aspect. That is, each of the plurality of capacitors C11 to C16 is used to step up or step down a voltage (input voltage) supplied from the pre-regulator circuit 10. More specifically, the plurality of capacitors C11 to C16 transfers electric charges between the capacitors C11 to C16 and the nodes N1 to N4 so that the voltages V1 to V4 (voltages with respect to a ground potential) that satisfy V1:V2:V3:V4=1:2:3:4 at the four nodes N1 to N4 are maintained. The plurality of voltages V1 to V4 corresponds to a plurality of discrete voltages, each having a plurality of discrete voltage levels. The voltage V1 is a voltage at the node N1, the voltage V2 is a voltage at the node N2, the voltage V3 is a voltage at the node N3, and the voltage V4 is a voltage at the node N4.

The capacitor C11 has two electrodes. One of the two electrodes of the capacitor C11 is connected to one end (first end) of the switch S11 and one end (first end) of the switch S12. The other of the two electrodes of the capacitor C11 is connected to one end (first end) of the switch S21 and one end (first end) of the switch S22.

The capacitor C12 has two electrodes. One of the two electrodes of the capacitor C12 is connected to one end (first end) of the switch S21 and one end (first end) of the switch S22. The other of the two electrodes of the capacitor C12 is connected to one end (first end) of the switch S31 and one end (first end) of the switch S32.

It is noted that that in the switched-capacitor circuit 20, the capacitor C12 is an example of a first capacitor. The one electrode of the two electrodes of the capacitor C12 forms a first electrode of the first capacitor, and the other electrode of the two electrodes of the capacitor C12 forms a second electrode of the first capacitor.

The capacitor C13 has two electrodes. One of the two electrodes of the capacitor C13 is connected to the one end (first end) of the switch S31 and the one end (first end) of the switch S32. The other electrode of the two electrodes of the capacitor C13 is connected to one end (first end) of the switch S41 and one end (first end) of the switch S42.

The capacitor C14 has two electrodes. One of the two electrodes of the capacitor C14 is connected to one end (first end) of the switch S13 and one end (first end) of the switch S14. The other electrode of the two electrodes of the capacitor C14 is connected to one end (first end) of the switch S23 and one end of the switch S24.

The capacitor C15 has two electrodes. One of the two electrodes of the capacitor C15 is connected to the one end (first end) of the switch S23 and the one end (first end) of the switch S24. The electrode other of the two electrodes of the capacitor C15 is connected to one end (first end) of the switch S33 and one end (first end) of the switch S34.

For purposes of this disclosure, it is noted that in the switched-capacitor circuit 20, the capacitor C15 is an example of a second capacitor. The one of the two electrodes of the capacitor C15 forms a third electrode of the second capacitor, and the other electrode of the two electrodes of the capacitor C15 forms a fourth electrode of the second capacitor.

The capacitor C16 has two electrodes. One of the two electrodes of the capacitor C16 is connected to the one end (first end) of the switch S33 and the one end (first end) of the switch S34. The other electrode of the two electrodes of the capacitor C16 is connected to one end (first end) of the switch S43 and one end (first end) of the switch S44.

Each of a set of the capacitors C11 and C14, a set of the capacitors C12 and C15, and a set of the capacitors C13 and C16 can complementarily perform charging and discharging by a first phase and a second phase being repeated.

In the first phase, the switches S12, S13, S22, S23, S32, S33, S42, and S43 are turned ON. As a result, for example, the one of the two electrodes (first electrode) of the capacitor C12 (first capacitor) is connected to the node N3, the other electrode of the two electrodes (second electrode) of the capacitor C12 and the one of the two electrodes of the capacitor C15 (third capacitor) are connected to the node N2, and the other electrode of the two electrodes of the capacitor C15 (fourth capacitor) is connected to the node N1.

In the second phase, the switches S11, S14, S21, S24, S31, S34, S41, and S44 are turned ON. As a result, for example, the one of the two electrodes (third electrode) of the capacitor C15 (second capacitor) is connected to the node N3, the other electrode of the two electrodes (fourth electrode) of the capacitor C15 (second capacitor) and the one of the two electrodes (first electrode) of the capacitor C12 (first capacitor) is connected to the node N2, and the other electrode of the two electrodes (second electrode) of the capacitor C12 (first capacitor) is connected to the node N1.

By the first phase and the second phase being repeated, while, for example, one of the capacitors C12 and C15 is being charged from the node N2, the other electrode of the capacitors C12 and C15 can discharge to the capacitor C23. That is, the capacitors C12 and C15 can complementarily perform charging and discharging. The capacitors C12 and C15 are a pair of flying capacitors that complementarily perform charging and discharging.

For purposes of this disclosure, it is noted that similarly to the set of the capacitors C12 and C15, the set of the capacitors C11 and C14 also becomes a pair of flying capacitors that complementarily performs charging from the node and discharging to a smoothing capacitor, by appropriately switching the switches. In addition, similarly to the set of capacitors C12 and C15, the set of the capacitors C13 and C16 also becomes a pair of flying capacitors that complementarily performs charging from the node and discharging to a smoothing capacitor, by appropriately switching the switches.

According to an exemplary aspect, each of the plurality of capacitors C21 to C24 can be configured to function as a smoothing capacitor. That is, each of the capacitors C21 to C24 is used for retaining and smoothing the voltages V1 to V4 at the nodes N1 to N4.

The capacitor C21 is connected between the node N1 and ground. Specifically, the one of the two electrodes of the capacitor C21 is connected to the node N1. Meanwhile, the other electrode of the two electrodes of the capacitor C21 (sixth electrode) is connected to ground.

The capacitor C22 is connected between the node N2 and the node N1. Specifically, the one of the two electrodes of the capacitor C22 is connected to the node N2. Meanwhile, the other electrode of the two electrodes of the capacitor C22 s connected to the node N1.

The capacitor C23 is connected between the node N3 and the node N2. Specifically, the one of the two electrodes of the capacitor C23 is connected to the node N3. Meanwhile, the other electrode of the two electrodes of the capacitor C23 is connected to the node N2.

The capacitor C24 is connected between the node N4 and the node N3. Specifically, the one of the two electrodes of the capacitor C24 is connected to the node N4. Meanwhile, the other electrode of the two electrodes of the capacitor C24 is connected to the node N3.

The switch S11 is connected between the one of the two electrodes of the capacitor C11 and the node N3. Specifically, the one end (first end) of the switch S11 is connected to the one of the two electrodes of the capacitor C11. Meanwhile, another end (second end) of the switch S11 is connected to the node N3.

The switch S12 is connected between the one of the two electrodes of the capacitor C11 and the node N4. Specifically, the one end (first end) of the switch S12 is connected to the one of the two electrodes of the capacitor C11. Meanwhile, another end (second end) of the switch S12 is connected to the node N4.

The switch S21 is connected between the one of the two electrodes (first electrode) of the capacitor C12 (first capacitor) and the node N2. Specifically, the one end (first end) of the switch S21 is connected to the one of the two electrodes (first electrode) of the capacitor C12 (first capacitor) and the other electrode of the two electrodes of the capacitor C11. Meanwhile, another end (second end) of the switch S21 is connected to the node N2. For purposes of this disclosure, it is noted that in the switched-capacitor circuit 20, the switch S21 is an example of a first switch.

The switch S22 is connected between the one of the two electrodes (first electrode) of the capacitor C12 and the node N3. Specifically, the one end (first end) of the switch S22 is connected to the one of the two electrodes (first electrode) of the capacitor C12 and the other electrode of the two electrodes of the capacitor C11. Meanwhile, another end (second end) of the switch S22 is connected to the node N3. For purposes of this disclosure, it is noted that in the switched-capacitor circuit 20, the switch S22 is an example of a third switch.

The switch S31 is connected between the other electrode of the two electrodes (second electrode) of the capacitor C12 (first capacitor) and the node N1. Specifically, the one end (first end) of the switch S31 is connected to the other electrode of the two electrodes (second electrode) of the capacitor C12 (first capacitor) and the one of the two electrodes of the capacitor C13. Meanwhile, another end (second end) of the switch S31 is connected to the node N1. For purposes of this disclosure, it is noted that in the switched-capacitor circuit 20, the switch S31 is an example of a fourth switch.

The switch S32 is connected between the other electrode of the two electrodes (second electrode) of the capacitor C12 (first capacitor) and the node N2. Specifically, the one end (first end) of the switch S32 is connected to the other electrode of the two electrodes (second electrode) of the capacitor C12 and the one of the two electrodes of the capacitor C13. Meanwhile, another end (second end) of the switch S32 is connected to the node N2. That is, the other end (second end) of the switch S32 is connected to the other end (second end) of the switch S21. For purposes of this disclosure, it is noted that in the switched-capacitor circuit 20, the switch S32 is an example of a second switch.

The switch S41 is connected between the other electrode of the two electrodes of the capacitor C13 and ground. Specifically, the one end (first end) of the switch S41 is connected to the other electrode of the two electrodes of the capacitor C13. Meanwhile, another end (second end) of the switch S41 is connected to ground.

The switch S42 is connected between the other electrode of the two electrodes of the capacitor C13 and the node N1. Specifically, the one end (first end) of the switch S42 is connected to the other electrode of the two electrodes of the capacitor C13. Meanwhile, another end (second end) of the switch S42 is connected to the node N1. That is, the other end (second end) of the switch S42 is connected to the other end (second end) of the switch S31.

The switch S13 is connected to the one of the two electrodes of the capacitor C14 and the node N3. Specifically, the one end (first end) of the switch S13 is connected to the one of the two electrodes of the capacitor C14. Meanwhile, another end (second end) of the switch S13 is connected to the node N3. That is, the other end of the switch S13 (second end) is connected to the other end (second end) of the switch S11 and the other end (second end) of the switch S22.

The switch S14 is connected between the one of the two electrodes of the capacitor C14 and the node N4. Specifically, the one end of the switch S14 is connected to the one of the two electrodes of the capacitor C14. Meanwhile, another end (second end) of the switch S14 is connected to the node N4. That is, the other end (second end) of the switch S14 is connected to the other end (second end) of the switch S12.

The switch S23 is connected between the one of the two electrodes (third electrode) of the capacitor C15 (second capacitor) and the node N2. Specifically, the one end (first end) of the switch S23 is connected to the one of the two electrodes (third electrode) of the capacitor C15 and the other electrode of the two electrodes of the capacitor C14. Meanwhile, another end (second end) of the switch S23 is connected to the node N2. That is, the other end (second end) of the switch S23 is connected to the other end (second end) of the switch S21 and the other end (second end) of the switch S32. For purposes of this disclosure, it is noted that in the switched-capacitor circuit 20, the switch S23 is an example of a fifth switch.

The switch S24 is connected between the one of the two electrodes (third electrode) of the capacitor C15 (second capacitor) and the node N3. Specifically, the one end (first end) of the switch S24 is connected to the one of the two electrodes (third electrode) of the capacitor C15 and the other electrode of the two electrodes of the capacitor C14. Meanwhile, another end (second end) of the switch S24 is connected to the node N3. That is, the other end (second end) of the switch S24 is connected to the other end (second end) of the switch S11, the other end (second end) of the switch S22, and the other end (second end) of the switch S13. For purposes of this disclosure, it is noted that in the switched-capacitor circuit 20, the switch S24 is an example of a seventh switch.

The switch S33 is connected between the other electrode of the two electrodes of the capacitor C15 (second capacitor) and the node N1. Specifically, the one end (first end) of the switch S33 is connected to the other electrode of the two electrodes (fourth electrode) of the capacitor C15 and the one of the two electrodes of the capacitor C16. Meanwhile, another end (second end) of the switch S33 is connected to the node N1. That is, the other end (second end) of the switch S33 is connected to the other end (second end) of the switch S31 and the other end (second end) of the switch S42. For purposes of this disclosure, it is noted that in the switched-capacitor circuit 20, the switch S33 is an example of an eighth switch.

The switch S34 is connected between the other electrode of the two electrodes (fourth electrode) of the capacitor C15 (second capacitor) and the node N2. Specifically, the one end (first end) of the switch S34 is connected to the other electrode of the two electrodes (fourth electrode) of the capacitor C15 and the one of the two electrodes of the capacitor C16. Meanwhile, another end (second end) of the switch S34 is connected to the node N2. That is, the other end (second end) of the switch S34 is connected to the other end (second end) of the switch S21, the other end (second end) of the switch S32, and the other end (second end) of the switch S23. For purposes of this disclosure, it is noted that in the switched-capacitor circuit 20, the switch S34 is an example of a sixth switch.

The switch S43 is connected between the other electrode of the two electrodes of the capacitor C16 and ground. Specifically, the one end (first end) of the switch S43 is connected to the other electrode of the two electrodes of the capacitor C16. Meanwhile, another end (second end) of the switch S43 is connected to ground.

The switch S44 is connected between the other electrode of the two electrodes of the capacitor C16 and the node N1. Specifically, the one end of the switch S44 is connected to the other electrode of the two electrodes of the capacitor C16. Meanwhile, another end (second end) of the switch S44 is connected to the node N1. That is, the other end (second end) of the switch S44 is connected to the other end (second end) of the switch S31, the other end (second end) of the switch S42, and the other end (second end) of the switch S33.

A first set of switches including the switches S12, S13, S22, S23, S32, S33, S42, and S43 and a second set of switches including the switches S11, S14, S21, S24, S31, S34, S41, and S44 are complementarily switched ON and OFF. Specifically, in the first phase, the first set of switches are turned ON, and the second set of switches are turned OFF. Conversely, in the second phase, the first set of switches are turned OFF, and the second set of switches are turned ON.

For example, in one of the first phase and the second phase, charging from the capacitors c11 to C13 to the capacitors c21 to C24 is performed. In the other of the first phase and the second phase, charging from the capacitors C14 to C16 to the capacitors C21 to C24 is performed. That is, since the capacitors C21 to C24 are charged from the capacitors C11 to C13 or from the capacitors C14 to C16 at all times, even when a current flows from the nodes N1 to N4 to the supply modulator 30 at high speed, the nodes N1 to N4 are replenished with electric charges at high speed. Therefore, fluctuations in potentials of the node N1 to N4 can be suppressed.

By operating as described above, the switched-capacitor circuit 20 can maintain approximately equal voltages at both ends of each of the capacitors C21 to C24. Specifically, the voltage V1 to V4 (voltages with respect to the ground potential) that satisfy V1:V2:V3:V4=1:2:3:4 are maintained at the four nodes N1 to N4. The voltage levels of the voltages V1 to V4 correspond to the plurality of discrete voltage levels supplied by the switched-capacitor circuit 20 to the supply modulator 30.

For purposes of this disclosure, it is noted that the voltage ratio V1:V2:V3:V4 is not limited to 1:2:3:4. For example, the voltage ratio V1:V2:V3:V4 may be 1:2:4:8 in an alternative exemplary aspect.

### (2.6) Supply Modulator

As illustrated in FIG. 6, the supply modulator 30 includes a plurality of (four in the example of FIG. 6) input terminals 131 to 134, a plurality of (four in the example of FIG. 6) the switches S51 to S54, an output terminal 130, and a control terminal 135.

The output terminal 130 is connected to the filter circuit 40. The output terminal 130 is a terminal for supplying, to the power amplifier 2, a voltage selected from among the voltages V1 to V4 as the power supply voltage Vcc, with the filter circuit 40 interposed therebetween.

The plurality of input terminals 131 to 134 is respectively connected to the nodes N4 to N1 of the switched-capacitor circuit 20. The plurality of input terminals 131 to 134 is terminals for receiving the voltages V4 to V1 from the switched-capacitor circuit 20.

The control terminal 135 is an input terminal for a control signal Sg3 from the digital control circuit 60. The control signal Sg3 is a signal for controlling ON/OFF of the plurality of switches S51 to S54 included in the supply modulator 30. The supply modulator 30 controls ON/OFF of the plurality of switches S51 to S54 based on the control signal Sg3.

The switch S51 is connected between the input terminal 131 and the output terminal 130. Specifically, the switch S51 has a first terminal connected to the input terminal 131 and a second terminal connected to the output terminal 130. In the above connection configuration, the switch S51 switches connection and non-connection between the input terminal 131 and the output terminal 130, by switching ON/OFF.

The switch S52 is connected between the input terminal 132 and the output terminal 130. Specifically, the switch S52 has a first terminal connected to the input terminal 132 and the second terminal connected to the output terminal 130. In the above connection configuration, the switch S52 switches connection and non-connection between the input terminal 132 and the output terminal 130, by switching ON/OFF. For purposes of this disclosure, it is noted that in the supply modulator 30, the switch S52 is an example of a tenth switch.

The switch S53 is connected between the input terminal 133 and the output terminal 130. Specifically, the switch S53 has a first terminal connected to the input terminal 133 and the second terminal connected to the output terminal 130. In the above connection configuration, the switch S53 switches connection and non-connection between the input terminal 133 and the output terminal 130, by switching ON/OFF. For purposes of this disclosure, it is noted that in the supply modulator 30, the switch S53 is an example of a ninth switch.

The switch S54 is connected between the input terminal 134 and the output terminal 130. Specifically, the switch S54 has a first terminal connected to the input terminal 134 and the second terminal connected to the output terminal 130. In the above connection configuration, the switch S54 switches connection and non-connection between the input terminal 134 and the output terminal 130, by switching ON/OFF.

The plurality of switches S51 to S54 is controlled to be exclusively ON. That is, only any of the switches S51 to S54 is turned ON and the remaining switches S51 to S54 are turned OFF. This configuration enables the supply modulator 30 to output the one voltage selected from the voltages V1 to V4.

By having the above-described configuration, the supply modulator 30 controls ON/OFF of the plurality of switches S51 to S54 based on the digital control signal that corresponds to the envelope signal and is input from the control terminal 135, to select at least one of the plurality of voltages V1 to V4 generated by the switched-capacitor circuit 20. The supply modulator 30 outputs the selected voltage.

There is a case where a waveform of the output voltage of the supply modulator 30 is not a rectangular wave that includes only a plurality of discrete voltages. Specifically, the waveform of the output voltage of the supply modulator 30 becomes a distorted waveform from a rectangular wave, where an overshoot voltage (spike-like voltage) occurs when transitioning from a discrete voltage of a relatively low voltage level to a discrete voltage of a relatively high voltage level. In addition, the waveform of the output voltage of the supply modulator 30 becomes distorted from a rectangular wave, where a undershoot voltage (spike-like voltage) occurs when transitioning from a discrete voltage of a relatively high voltage level to a discrete voltage of a relatively low voltage level. The above-described waveform distortion of the output voltage of the supply modulator 30 causes noise. The larger an absolute value of the voltage change rate (dV/dt), the larger the amplitude of the spike-like voltage.

### (2.7) Band Select Switch Circuit

As illustrated in FIG. 6, the band select switch circuit 50 includes a common terminal 150, a plurality of (four in the example of FIG. 6) switches S81 to S84, a plurality of (four in the example of FIG. 6) selection terminals 151 to 154, and a control terminal 155.

The common terminal 150 of the band select switch circuit 50 is connected to the output terminal 130 of the supply modulator 30. For example, a plurality of power amplifiers corresponding to mutually different communication bands is respectively connected to the plurality of selection terminals 151 to 154. In the example illustrated in FIG. 3, the power amplifier 2 is connected to the one selection terminal 151 of the plurality of selection terminals 151 to 154 with the filter circuit 40 interposed therebetween.

The control terminal 155 is an input terminal for a control signal Sg4. That is, the control terminal 155 is a terminal for receiving the control signal Sg4 that indicates one of the plurality of communication bands. The band select switch circuit 50 controls ON/OFF of the plurality of switches S81 to S84 so that the power amplifier corresponding to the communication band indicated by the control signal Sg4 is connected to the supply modulator 30.

The switch S81 is connected between the common terminal 150 and the selection terminal 151. Specifically, the switch S81 has a first terminal connected to the common terminal 150 and a second terminal connected to the selection terminal 151. In the above connection configuration, the switch S81 switches connection and non-connection between the common terminal 150 and the selection terminal 151, by switching ON/OFF.

The switch S82 is connected between the common terminal 150 and the selection terminal 152. Specifically, the switch S82 has the first terminal connected to the common terminal 150 and a second terminal connected to the selection terminal 152. In the above connection configuration, the switch S82 switches connection and non-connection between the common terminal 150 and the selection terminal 152, by switching ON/OFF.

The switch S83 is connected between the common terminal 150 and the selection terminal 153. Specifically, the switch S83 has the first terminal connected to the common terminal 150 and a second terminal connected to the selection terminal 153. In the above connection configuration, the switch S83 switches connection and non-connection between the common terminal 150 and the selection terminal 153, by switching ON/OFF.

The switch S84 is connected between the common terminal 150 and the selection terminal 154. Specifically, the switch S84 has the first terminal connected to the common terminal 150 and a second terminal connected to the selection terminal 154. In the above connection configuration, the switch S84 switches connection and non-connection between the common terminal 150 and the selection terminal 154, by switching ON/OFF.

In the example of FIG. 6, the plurality of switches S81 to S84 is controlled to be exclusively ON. That is, only any of the switches S81 to S84 is turned ON and the remaining switches S81 to S84 are turned OFF.

### (2.8) Filter Circuit

As illustrated in FIG. 1, the filter circuit 40 includes an input terminal 141, an output terminal 142, an inductor L0, a plurality of (two in the example of FIG. 1) LC series circuits (first LC series circuit 41 and second LC series circuit 42), a plurality of (two in the example of FIG. 1) switches (first changeover switch SW1 and second changeover switch SW2).

The input terminal 141 is an input terminal for the voltage selected by the supply modulator 30. That is, the input terminal 141 is a terminal for receiving the voltage selected from the plurality of voltages V1 to V4. For purposes of this disclosure, it is noted that in the example of FIG. 1, the input terminal 141 is connected to the output terminal 130 (see, e.g., FIG. 6) of the supply modulator 30 with the band select switch circuit 50 interposed therebetween.

The output terminal 142 is a terminal to which a voltage filtered by the filter circuit 40 is output. A voltage output from the output terminal 142 of the filter circuit 40 is the power supply voltage Vcc supplied to the power amplifier 2 (see, e.g., FIG. 4).

The inductor L0 is connected between the input terminal 141 and the output terminal 142. More specifically, one end (first end) of the inductor L0 is connected to the input terminal 141, and another end (second end) of the inductor L0 is connected to the output terminal 142.

The plurality of LC series circuits includes the first LC series circuit 41 and the second LC series circuit 42.

The first LC series circuit 41 includes an inductor L1 and the variable capacitor VC1. The inductor L1 and the variable capacitor VC1 are connected in series between the one end of the inductor L0 and ground. More specifically, one end (first end) of the inductor L1 is connected to the one end (first end) of the inductor L0 with the first changeover switch SW1 interposed therebetween, and another end (second end) of the inductor L1 is connected to one of two electrodes of the variable capacitor VC1, and the other electrode of the two electrodes of the variable capacitor VC1 is connected to ground.

The variable capacitor VC1 is, for example, a DTC (Digital Tunable Capacitor) whose capacitance is variable. The variable capacitor VC1 includes the plurality of (four in the example of FIG. 1) capacitors CA11 to CA14 and the plurality of switches SW11 to SW14. The plurality of capacitors CA11 to CA14 corresponds one-to-one to the plurality of switches SW11 to SW14, and each of the plurality of capacitors CA11 to CA14 is connected in series to a corresponding switch of the plurality of switches SW11 to SW14. The capacitance of the variable capacitor VC1 is varied by switching ON/OFF of each of the plurality of switches SW11 to SW14.

The second LC series circuit 42 includes an inductor L2 and the variable capacitor VC2. The inductor L2 and the variable capacitor VC2 are connected in series between the other end of the inductor L0 and ground. More specifically, one end (first end) of the inductor L2 is connected to the other end (second end) of the inductor L0, another end (second end) of the inductor L2 is connected to one of two electrodes of the variable capacitor VC2, and the other electrode of the two electrodes of the variable capacitor VC2 is connected to ground.

The variable capacitor VC2 is, for example, a DTC (Digital Tunable Capacitor) whose capacitance is variable. The variable capacitor VC2 includes a plurality of (four in the example of FIG. 1) capacitors CA21 to CA24 and a plurality of switches SW21 to SW24. The plurality of capacitors CA21 to CA24 corresponds one-to-one to the plurality of switches SW21 to SW24, and each of the plurality of capacitors CA21 to CA24 is connected in series to a corresponding switch of the plurality of switches SW21 to SW24. The capacitance of the variable capacitor VC2 is varied by switching ON/OFF of each of the plurality of switches SW21 to SW24.

The filter circuit 40 forms a low pass filter. This configuration enables the filter circuit 40 to reduce radio frequency components contained in the power supply voltage Vcc. For example, when a predetermined band is a frequency band for frequency division duplex (FDD: Frequency Division Duplex), the filter circuit 40 is configured to reduce components of a downlink operation band of the predetermined band.

Filter characteristics of the filter circuit 40 have two attenuation poles. A frequency of one of the two attenuation poles is determined by respective circuit constants of the inductor L1 and the variable capacitor VC1 of the first LC series circuit 41. In addition, a frequency of the other of the two attenuation poles is determined by respective circuit constants of the inductor L2 and the variable capacitor VC2 of the second LC series circuit 42.

The filter circuit 40 reduces the amplitude of the spike-like voltage in the output voltage output from the supply modulator 30. That is, by including the filter circuit 40, the power supply circuit 1 can reduce the waveform distortion in the output voltage output from the supply modulator 30, thereby reducing the radio frequency components in the output voltage mentioned above. This configuration reduces noise contained in the power supply voltage Vcc in the power supply circuit 1, so that noise entering the power amplifier 2 from the power supply circuit 1 is also reduced.

### (2.9) Digital Control Circuit

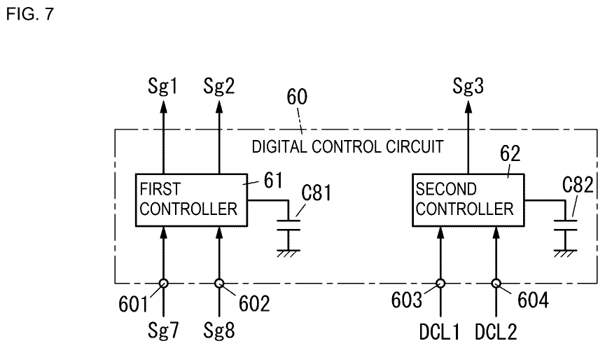

As illustrated in FIG. 7, the digital control circuit 60 includes a first controller 61, a second controller 62, two capacitors C81 and C82, and four control terminals 601 to 604. The four control terminals 601 to 604 of the digital control circuit 60 are connected in a one-to-one relationship to the four second control terminals T5 (see, e.g., FIG. 4) included in the high frequency system 200. Therefore, the four control terminals 601 to 604 of the digital control circuit 60 are connected to the RF signal processing circuit 51 (see, e.g., FIG. 4) of the communication device 7.

The first controller 61 receives, from the RF signal processing circuit 51, a source-synchronous digital control signal with the control terminals 601 and 602 interposed therebetween, and processes the digital control signal mentioned above to generate the control signal Sg1 and the control signal Sg2.

In the first controller 61, one set of a clock signal Sg7 and a data signal Sg8 is used as a digital control signal for the pre-regulator circuit 10 and the switched-capacitor circuit 20. The clock signal Sg7 is input into the first controller 61 with the control terminal 601 interposed therebetween. The data signal Sg8 is input into the first controller 61 with the control terminal 602 interposed therebetween.

The second controller 62 processes digitally-controlled level signals DCL1 and DCL2, which are digital control signals received from the RF signal processing circuit 51 with the control terminals 603 and 604 interposed therebetween, and generates the control signal SG3. The digitally-controlled level signals DCL1 and DCL2 correspond to envelope signals.

Each of the digitally-controlled level signals DCL1 and DCL2 is a 1-bit signal. Each of the voltages V1 to V4 is represented by a combination of two 1-bit signals. For example, V1, V2, V3, and V4 are represented by “00”, “01”, “10”, and “11”, respectively. A gray code (Gray code) may be used to represent the voltage levels. For purposes of this disclosure, it is noted that in the above-mentioned case, the two digitally-controlled level signals are used to control the supply modulator 30, but the number of the digitally-controlled level signals is not limited to two. For example, one or an arbitrary number of digitally-controlled level signals, such as three or more, may be used depending on the number of voltage levels that can be selected by the supply modulator 30. In addition, the digital control signal used for control of the supply modulator 30 is not limited to the digitally-controlled level signal.

The capacitor C81 is connected between the first controller 61 and ground. For example, the capacitor C81 is connected between a power supply line that supplies electric power to the first controller 61 and the ground, and is configured to function as a bypass capacitor. The capacitor C82 is connected between the second controller 62 and ground. For example, the capacitor C82 is connected between a power supply line that supplies electric power to the second controller 62 and the ground, and is configured to function as a bypass capacitor.

### (3) Structure of Tracker Module

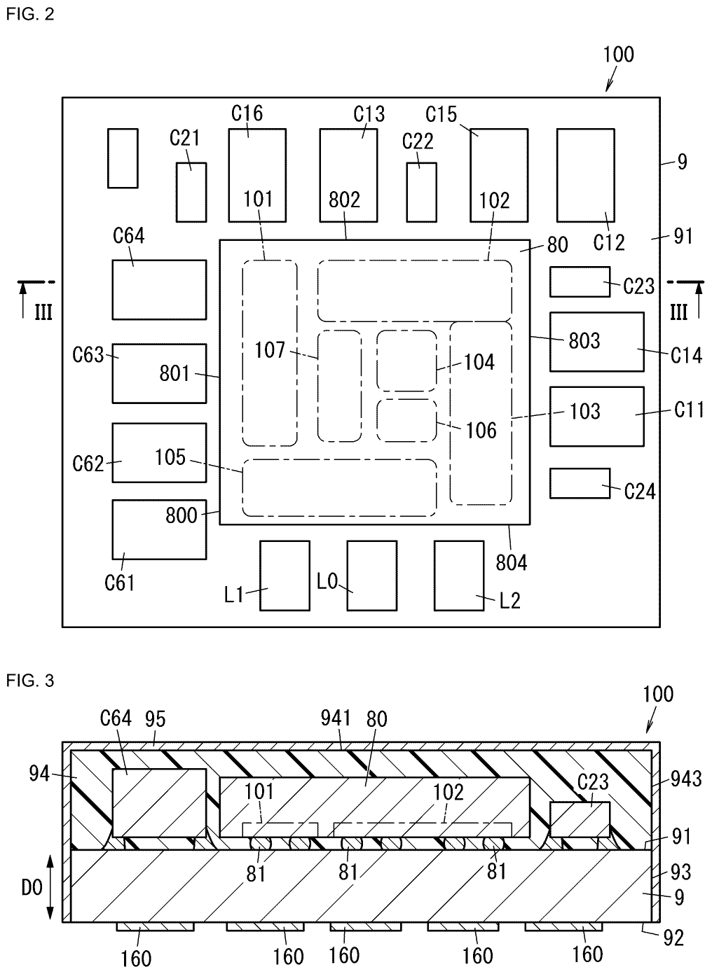

As illustrated in FIGS. 1 to 3, the tracker module 100 according to Exemplary Embodiment 1 includes the module laminate 9, the IC chip 80, the plurality of (ten in the example of FIG. 1) capacitors C11 to C16 and C21 to C24 of the switched-capacitor circuit 20, the plurality of (four in the example of FIG. 1) capacitors C61 to C64 of the pre-regulator circuit 10, and a plurality of external connection terminals 160. In addition, the tracker module 100 according to Exemplary Embodiment 1 further includes a resin layer 94 and a shield electrode layer 95. The tracker module 100 according to Exemplary Embodiment 1 has a circuit configuration where the power inductor L71 is excluded from the circuit configuration of the power supply circuit 1. That is, the tracker module 100 does not include the power inductor L71. For purposes of this disclosure, it is noted that in FIG. 2, illustration of the resin layer 94 and the shield electrode layer 95 is omitted.

### (3.1) Module Laminate

As illustrated in FIGS. 1 to 3, the module laminate 9 includes a first principal surface 91 and a second principal surface 92 that face each other in a thickness direction DO of the module laminate 9. Here, the term “facing” can indicate geometrically facing, and not physically facing. In a plan view of the thickness direction DO of the module laminate 9, an outer edge of the module laminate 9 is, for example, rectangular, but may be any shape other than rectangular. The module laminate 9 is, for example, a multilayer substrate in which a plurality of dielectric layers and a plurality of conductive layers are laminated (not illustrated). A material of each conductive layer is, for example, copper. The plurality of conductive layers includes a ground layer. The ground layer of the module laminate 9 is electrically connected to at least one external ground terminal included in the plurality of external connection terminals 160, with a via conductor of the module laminate 9, and the like, interposed therebetween.

The module laminate 9 is, for example, a LTCC (Low Temperature Co-fired Ceramics) substrate. For purposes of this disclosure, it is noted that the module laminate 9 is not limited to the LTCC substrate, and may be, for example, a printed wiring board, a HTCC (High Temperature Co-fired Ceramics) substrate, a resin multilayered substrate, or a component embedded board.

### (3.2) IC Chip

As illustrated in FIGS. 1 to 3, the IC chip 80 is disposed on the module laminate 9. More specifically, the IC chip 80 is disposed on the first principal surface 91 of the module laminate 9. The IC chip 80 is, for example, a Si-based IC chip including a silicon substrate. The Si-based IC chip may include an SOI (Silicon on Insulator) substrate, instead of a silicon substrate. The IC chip 80 is not limited to the Si-based IC chip, and may be, for example, a GaAs-based IC chip, an SiGe-based IC chip, or a GaN-based IC chip.

An outer edge 800 of the IC chip 80 is rectangular in a plan view of the thickness direction DO of the module laminate 9. The outer edge 800 of the IC chip 80 includes a first side 801, a second side 802, a third side 803, and a fourth side 804. The first side 801, the second side 802, the third side 803, and the fourth side 804 are arranged in an order of the first side 801, the second side 802, the third side 803, and the fourth side 804. In the outer edge 800, the first side 801 and the third side 803 are parallel to each other, and the second side 802 and the fourth side 804 are parallel to each other.

As illustrated in FIG. 2, the IC chip 80 has a PR switch portion (first switch portion) 101, an SC switch portion (second switch portion) 102, an SC switch portion (third switch portion) 103, an SM switch portion (fourth switch portion) 104, a BS switch portion (fifth switch portion) 105, a digital control unit 107, and a plurality of input/output electrodes 81.

The PR switch portion 101 includes the plurality of switches S61 to S63, S71, and S72 (see, e.g., FIG. 3) of the pre-regulator circuit 10. In the IC chip 80, the PR switch portion 101 is disposed along the first side 801.

The SC switch portion 102 includes the plurality of switches S11, S12, S21, S22, S31, S32, S41, and S42 of the switched-capacitor circuit 20 (see, e.g., FIG. 6).

Specifically, the SC switch portion 102 includes series circuits of the plurality of switches S11, S12, S21, S22, S31, S32, S41, and S42. In the IC chip 80, the SC switch portion 102 is disposed along the second side 802.

The SC switch portion 103 includes the plurality of switches S13, S14, S23, S24, S33, S34, S43, and S44 of the switched-capacitor circuit 20 (see, e.g., FIG. 6). Specifically, the SC switch portion 103 includes series circuits of the plurality of switches S13, S14, S23, S24, S33, S34, S43, and S44. In the IC chip 80, the SC switch portion 103 is disposed along the third side 803.

The SM switch portion 104 includes the plurality of switches S51 to S54 of the supply modulator 30 (see, e.g., FIG. 6). In the IC chip 80, the SM switch portion 104 is disposed along the SC switch portion 102 and the SC switch portion 103.

The BS switch portion 105 includes the plurality of switches S81 to S84 of the band select switch circuit 50 (see, e.g., FIG. 6). In the IC chip 80, the BS switch portion 105 is disposed so as to be adjacent to the SM switch portion 104.

The digital control unit 107 has the first controller 61 and the second controller 62 of the digital control circuit 60 (see, e.g., FIG. 7). In a plan view of the thickness direction DO of the module laminate 9, the digital control unit 107 is disposed in a midportion of the IC chip 80, and is surrounded by the PR switch portion 101, the SC switch portion 102, the SM switch portion 104, and the BS switch portion 105.

In the IC chip 80, the plurality of switches S11 to S14, S21 to S24, S31 to S34, S41 to S44, S51 to S54, S61 to S63, S71, S72, S81 to S84 is each, for example, a MOSFET (Metal Oxide Semiconductor Field Effect Transistor).

### (3.3) Plurality of Capacitors of Switched-Capacitor Circuit and Plurality of Capacitors of Pre-regulator Circuit

As illustrated in FIG. 6, the plurality of (ten in the example of FIG. 6) capacitors C11 to C16 and C21 to C24 of the switched-capacitor circuit 20 and the plurality of (four in the example of FIG. 6) capacitors C61 to C64 of the pre-regulator circuit 10 are disposed on the module laminate 9. More specifically, the plurality of capacitors C11 to C16 and C21 to C24 and the plurality of capacitors C61 to C64 are disposed on the first principal surface 91 of the module laminate 9. The plurality of capacitors C11 to C16 and C21 to C24 and the plurality of capacitors C61 to C64 are each a chip capacitor. That is, the plurality of capacitors C11 to C16 and C21 to C24 and the plurality of capacitors C61 to C64 are each a surface-mount type capacitor.

In the tracker module 100, in a plan view of the thickness direction DO of the module laminate 9, the IC chip 80 is adjacent to the capacitor C11, the IC chip 80 is adjacent to the capacitor C12, the IC chip 80 is adjacent to the capacitor C13, the IC chip 80 is adjacent to the capacitor C14, the IC chip 80 is adjacent to the capacitor C15, and the IC chip 80 is adjacent to the capacitor C16. For purposes of this disclosure, the phrase “the IC chip 80 is adjacent to the capacitor” can indicate that in a plan view of the thickness direction DO of the module laminate 9, the IC chip 80 and the capacitor are disposed on the first principal surface 91 of the module laminate 9, with no other circuit component between the IC chip 80 and the capacitor.

In the tracker module 100, in a plan view of the thickness direction DO of the module laminate 9, the plurality of capacitors C11 to C16 and C21 to C24 of the switched-capacitor circuit 20 are disposed along the second side 802 or the third side 803 of the IC chip 80.

More specifically, in the tracker module 100, in a plan view of the thickness direction DO of the module laminate 9, the capacitors C13, C16, and C21 are adjacent to the second side 802 of the IC chip 80. As described above, the capacitor C13 and the capacitor C16 are a pair of flying capacitors that complementarily perform charging and discharging. The capacitor C21 is a smoothing capacitor that smooths a voltage of each of the capacitors C13 and C16 and a voltage of the node N1. In the tracker module 100, in a plan view of the thickness direction DO of the module laminate 9, the capacitor C21 is disposed between the capacitor C13 and the capacitor C16.

In the tracker module 100, in a plan view of the thickness direction DO of the module laminate 9, the plurality of capacitors C61 to C64 is adjacent to the IC chip 80. In a plan view of the thickness direction DO of the module laminate 9, the plurality of capacitors C61 to C64 of the pre-regulator circuit 10 is disposed along the first side 801 of the IC chip 80.

Incidentally, in the tracker module 100, the plurality of variable capacitors VC1 and VC2 of the filter circuit 40 is integrated in the IC chip 80. In the IC chip 80, in a plan view of the thickness direction DO of the module laminate 9, the SM switch portion 104 in which the plurality of switches S51 to S54 of the supply modulator 30 is formed is adjacent to a functional element portion 106 in which the plurality of variable capacitors VC1 and VC2 of the filter circuit 40 is formed.

In addition, in the tracker module 100 according to Exemplary Embodiment 1, the inductors L0, L1, and L2 of the filter circuit 40 are disposed on the module laminate 9. More specifically, the inductors L0, L1, and L2 are disposed on the first principal surface 91 of the module laminate 9. Each of the inductors L0, L1, and L2 is a chip inductor. That is, each of the inductors L0, L1, and L2 is a surface-mount inductor.

In a plan view of the thickness direction DO of the module laminate 9, the inductors L0, L1, and L2 of the filter circuit 40, which are not integrated in the IC chip 80, are adjacent to the IC chip 80. In a plan view of the thickness direction DO of the module laminate 9, the inductors L0, L1, and L2 of the filter circuit 40, which are not integrated in the IC chip 80, are adjacent to the BS switch portion 105 of the IC chip 80.

### (3.4) Input/Output Electrode

As illustrated in FIG. 3, the plurality of input/output electrodes 81 is electrically connected to circuit components other than the IC chip 80 disposed on the first principal surface 91 of the module laminate 9 or to the plurality of external connection terminals 160 disposed on the second principal surface 92 of the module laminate 9, and the like, with a wiring section, a via conductor section, and the like formed on the module laminate 9, interposed therebetween.

### (3.5) External Connection Terminal

The plurality of external connection terminals 160 illustrated in FIG. 3 includes an input terminal 161 (see, e.g., FIG. 4), a plurality of (four) input control terminals 165 (only one of which is illustrated in FIG. 4), an output terminal 164 (see, e.g., FIG. 4), and a ground terminal (not illustrated). The input terminal 161 is connected to the input terminal 110 of the pre-regulator circuit 10. The input terminal 161 is a terminal that is connected to the direct current power source 70 with the power supply connection terminal T4, which is included in the high frequency system 200, interposed therebetween. That is, the input terminal 110 of the pre-regulator circuit 10 is connected to the direct current power source 70 with the input terminal 161 interposed therebetween. The four input control terminals 165 are terminals connected to the four second control terminals T5. The four input control terminals 165 are connected to the control terminals 601 to 604 of the digital control circuit 60. The output terminal 164 is connected to the output terminal 142 of the filter circuit 40. The output terminal 164 is a terminal to which the power supply voltage Vcc is output and is connected to the power supply terminal of the power amplifier 2. The plurality of ground terminals is a terminal to which the ground potential is given.

### (3.6) Resin Layer

As illustrated in FIG. 3, the resin layer 94 is disposed on the first principal surface 91 of the module laminate 9, and covers a portion of each of a plurality of circuit components included in the tracker module 100 and the first principal surface 91 of the module laminate 9. The plurality of circuit components includes the IC chip 80 0, the plurality of capacitors C11 to C16, the plurality of capacitors C21 to C24, and the plurality of capacitors C61 to C64. The resin layer 94 contains a resin (epoxy resin, for example). The resin layer 94 may contain a filler in addition to the resin. The resin layer 94 has electric insulating properties.

### (3.7) Shield Electrode Layer

As illustrated in FIG. 3, the shield electrode layer 95 encompasses the resin layer 94 and the module laminate 9. More particularly, the shield electrode layer 95 encompasses a principal surface 941 and an outer peripheral surface 943 of the resin layer 94, and an outer peripheral surface 93 of the module laminate 9.

The shield electrode layer 95 is conductive. In the tracker module 100, the shield electrode layer 95 is a shield layer provided for the purpose of electromagnetic shielding the inside and the outside of the tracker module 100. The shield electrode layer 95 is in contact with at least a portion of an outer peripheral surface of the ground layer of the module laminate 9. This configuration enables a potential of the shield electrode layer 95 to be the same as a potential of the ground layer. Although the shield electrode layer 95 has a multilayer structure in which a plurality of metal layers is laminated, the shield electrode layer 95 is not limited to a multilayer structure, and may be a single metal layer. The metal layer contains one or more types of metal.

### (3.8) Arrangement of Tracker Module

The tracker module 100 illustrated in FIGS. 2 and 3 is disposed, for example, on a motherboard (not illustrated) included in the high frequency system 200 (see, e.g., FIG. 4). More specifically, the tracker module 100 is electrically and mechanically connected to the motherboard through the plurality of external connection terminals 160. As a result, in the high frequency system 200, for example, the output terminal of the tracker module 100 (output terminal 142 of the filter circuit 40) is connected to the power supply terminal of the power amplifier 2 (see, e.g., FIG. 4) disposed on the motherboard.

### (4) Structure of High Frequency System

The high frequency system 200 illustrated in FIG. 4 includes the motherboard (not illustrated) and a plurality of electronic components disposed on the motherboard. The motherboard is, for example, a printed wiring board. The plurality of electronic components includes the tracker module 100 (see, e.g., FIG. 2), the power inductor L71 (see, e.g., FIG. 6), the power amplifier 2 (FIG. 4), and the filter 3 (see, e.g., FIG. 4).

### (5) Structure of Communication Device

As illustrated in FIG. 4, the communication device 7 includes the high frequency system 200, the signal processing circuit 5 disposed on the motherboard (not illustrated) of the high frequency system 200, and the antenna 6. For purposes of this disclosure, it is noted that the communication device 7 may include a second motherboard on which the high frequency system 200 and the signal processing circuit 5 are disposed, separately from a first motherboard that is the motherboard of the high frequency system 200.

### (6) Technical Effects

In the tracker module 100 according to Exemplary Embodiment 1, at least one of the switches SW11 to SW14 and SW21 to SW24 of the variable capacitors (variable reactance elements) VC1 and VC2 in the filter circuit 40 is integrated in the IC chip 80. This configuration reduces a size of the tracker module 100, as compared to a case in which the switches SW11 to SW14 and SW21 to SW24 of the variable capacitors VC1 and vC2 are not integrated in the IC chip 80.

In the tracker module 100 according to Exemplary Embodiment 1, at least one of the switches S11 to S14, S21 to S24, S31 to S34, and S41 to S44 of the switched-capacitor circuit 20 is provided in the IC chip 80. This configuration further reduces the size of the tracker module 100, as compared to a case in which the switches S11 to S14, S21 to S24, S31 to S34, and S41 to S44 of the switched-capacitor circuit 20 are not provided in the IC chip 80.

In the tracker module 100 according to Exemplary Embodiment 1, the capacitors (reactance elements) CA11 to CA14 and CA21 to CA24 of the variable capacitors (variable reactance elements) VC1 and VC2 in the filter circuit 40 are integrated in the IC chip 80, together with the switches SW11 to SW14 and SW21 to SW24. This configuration further reduces the size as compared to a case in which the capacitors CA11 to CA14 and CA21 to CA24 in the filter circuit 40 are not integrated in the IC chip 80.

In the tracker module 100 according to Exemplary Embodiment 1, the switches SW11 to SW14 and SW21 to SW24 of the variable capacitor (variable reactance elements) VC1 and VC2 in the filter circuit 40 are adjacent to the switches S51 to S54 of the supply modulator 30. This configuration shortens a wiring length between the supply modulator 30 and the filter circuit 40.

In the tracker module 100 according to Exemplary Embodiment 1, the filter circuit 40 has the first LC series circuit 41 and the second LC series circuit 42. This configuration further reduces harmonic waves.

In the tracker module 100 according to Exemplary Embodiment 1, the filter circuit 40 further includes the first changeover switch SW1 connected in series to the first LC series circuit 41 and the second changeover switch SW2 connected in series to the second LC series circuit 42. This makes it to change the attenuation poles in the filter characteristics of the filter circuit 40.

In the high frequency system 200 according to Exemplary Embodiment 1, in the tracker module 100, at least one of the switches SW11 to SW14 and SW21 to SW24 of the variable capacitors (variable reactance elements) VC1 and VC2 in the filter circuit 40 is integrated in the IC chip 80. This configuration reduces the size as compared to a case in which the switches SW11 to SW14 and SW21 to SW24 of the variable capacitors VC1 and VC2 are not integrated in the IC chip 80.

In the communication device 7 according to Exemplary Embodiment 1, in the tracker module 100 provided in the high frequency system 200, at least one of the switches SW11 to SW14 and SW21 to SW24 of the variable capacitors (variable reactance elements) VC1 and VC2 in the filter circuit 40 is integrated in the IC chip 80. This configuration reduces the size as compared to a case in which the switches SW11 to SW14 and SW21 to SW24 of the variable capacitors VC1 and VC2 are not integrated in the IC chip 80.

### (7) Modification Example of Exemplary Embodiment 1

In the following, a modification example of Exemplary Embodiment 1 will be described.

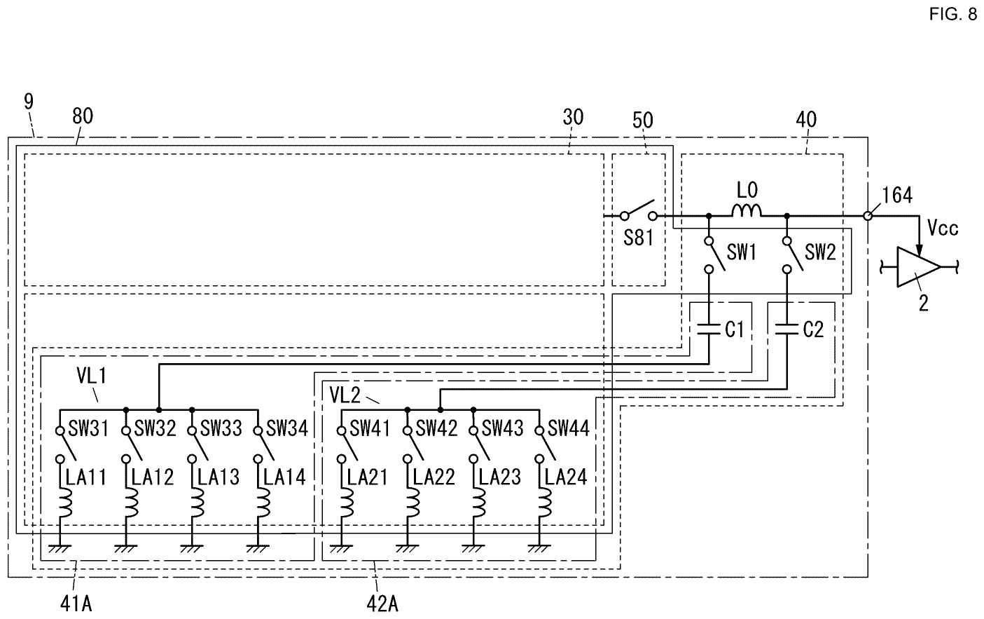

A tracker module 100 according to a modification example of Exemplary Embodiment 1 differs from the tracker module 100 (see, e.g., FIG. 1) according to Exemplary Embodiment 1 in that as illustrated in FIG. 8, the filter circuit 40 has a first LC series circuit 41A and a second LC series circuit 42A, instead of the first LC series circuit 41 and the second LC series circuit 42.

The first LC series circuit 41A includes the capacitor C1 and a variable inductor VL1. The capacitor C1 and the variable inductor VL1 are connected in series between the one end of the inductor L0 and ground. More specifically, one end of the capacitor C1 (first end) is connected to the one end (first end) of the inductor L0, and another end (second end) of the capacitor C1 is connected to one of two electrodes of the variable inductor VL1, and the other electrode of two electrodes of the variable inductor VL1 is connected to ground.

The variable inductor VL1 includes a plurality of (four in the example of FIG. 8) inductors LA11 to LA14 and a plurality of switches SW31 to SW34. The plurality of inductors LA11 to LA14 corresponds one-to-one to the plurality of switches SW31 to SW34, and each of the plurality of inductors LA11 to LA14 is connected in series to a corresponding switch of the plurality of switches SW31 to Sw34. The inductance of the variable inductor VL1 is varied by switching ON/OFF each of the plurality of switches SW31 to SW34.

The second LC series circuit 42A includes the capacitor C2 and a variable inductor VL2. The capacitor C2 and the variable inductor VL2 are connected in series between the other end of the inductor L0 and ground. More specifically, one end (first end) of the capacitor C2 is connected to the other end (second end) of the inductor L0, another end (second end) of the capacitor C2 is connected to one of two electrodes of the variable inductor VL2, and the other electrode of the two electrodes of the variable inductor VL2 is connected to ground.

The variable inductor VL2 includes a plurality of (four in the example of FIG. 8) inductors LA21 to LA 24 and a plurality of switches SW41 to SW44. The plurality of inductors LA21 to lA24 corresponds one-to-one to the plurality of switches SW41 to SW44, and each of the plurality of inductors LA21 to LA24 is connected in series to a corresponding switch of the plurality of switches SW41 to Sw44. The inductance of the variable inductor VL2 is varied by switching ON/OFF each of the plurality of switches SW41 to SW44.

In the tracker module 100 according to the modification example of Exemplary Embodiment 1, the variable inductors VL1 and VL2 of the filter circuit 40 are integrated in the IC chip 80. In the IC chip 80, in a plan view of the thickness direction DO of the module laminate 9, the SM switch portion 104 where the plurality of switches S51 to S54 of the supply modulator 30 is formed is adjacent to the functional element portion 106 in which the plurality of variable inductors VL1 and VL2 of the filter circuit 40 is formed.

In addition, in the tracker module 100 according to the modification example of Exemplary Embodiment 1, although not illustrated, the inductor L0 and the capacitors C1 and C2 of the filter circuit 40 are disposed on the module laminate 9. More specifically, the inductor L0 and the capacitors C1 and C2 are disposed on the first principal surface 91 of the module laminate 9. The inductor L0 is a chip inductor, and each of the capacitors C1 and C2 is a chip capacitor. That is, the inductor L0 is a surface-mount type inductor, and each of the capacitors C1 and C2 is a surface-mount type capacitor.

### Additional Modification Examples

It is noted that the tracker module 100 may only include at least one of the capacitors C11 to C16 and C21 to C24 included in the switched-capacitor circuit 20, among the above-mentioned capacitors C11 to C16, C21 to C24, and C61 to C64. In addition, the IC chip 80 may only include at least one of the plurality of switches S11 to S14, S21 to S24, s31 to S34, and S41 to S44 for the switched-capacitor circuit 20. In addition, the IC chip 80 may only include at least one of the plurality of switches S51 to S54 for the supply modulator 30.

In addition, in the tracker module 100, the IC chip 80 may not have the PR switch portion 101 and the BS switch portion 105 in an exemplary aspect. Therefore, for example, a second IC chip, which is different from the IC chip 80 (first IC chip), may have the PR switch portion 101 and the BS switch portion 105. In this case, it is sufficient that on the module laminate 9, at least the IC chip 80 out of the IC chip 80 and the second IC chip may be disposed, only the IC chip 80 may be disposed, or both the IC chip 80 and the second IC chip may be disposed.

In addition, the tracker module 100 may be such configured that the tracker module 100 does not include the shield electrode layer 95. In addition, the tracker module 100 may be configured that the tracker module 100 does not include the resin layer 94 and the shield electrode layer 95.

In addition, the pre-regulator circuit 10, the switched-capacitor circuit 20, the supply modulator 30, the band select switch circuit 50, and the filter circuit 40 are not limited to the circuit configuration illustrated in FIG. 6.

For example, although the switched-capacitor circuit 20 is configured to be able to supply the voltages V1, V2, V3, and V4 at the four discrete voltage levels in FIG. 6, the switched-capacitor circuit 20 is not limited to being configured to supply voltages of the four discrete voltage levels. The switched-capacitor circuit 20 may be configured to be able to supply voltages of any number, such as two or more, of discrete voltage levels. For example, when the switched-capacitor circuit 20 is configured to be able to supply voltages of two discrete voltage levels, it is sufficient for the switched-capacitor circuit 20 to include, for example, at least the capacitors C12 and C15, and the switches S21, S22, S31, S32, S23, S24, S33, and S34.

In addition, in the switched-capacitor circuit 20, not only the capacitor C12 is an example of the first capacitor, but also the capacitor C11 or C13 may be an example of the first capacitor. In addition, in the switched-capacitor circuit 20, not only the capacitor C15 is an example of the second capacitor, but also the capacitor C14 or C16 may be an example of the second capacitor.

In addition, a configuration of the supply modulator 30 is not limited to the configuration illustrated in FIG. 6. In particular, the switches S51 to S54 may have any configuration as long as the switches S51 to S54 can select any of the four input terminals 131 to 134 and couple it to the output terminal 130. For example, the supply modulator 30 may further include a switch connected between the switches S51 to S53, the switches S54, and the output terminal 130. In addition, the supply modulator 30 may further include a switch connected between the switches S51 and S52, the switches S53 and S54, and the output terminal 130.

In addition, for example, when one voltage is selected from two discrete voltage levels, it is sufficient for the supply modulator 30 to include at least the switches S52 and S53.

In addition, the filter circuit 40 illustrated in FIG. 6 forms a low pass filter, but the filter circuit 40 not only form a low pass filter but also may form a band pass filter or a high pass filter.

In addition, a digital control signal processed by the first controller 61 is not limited to a source-synchronous digital control signal. For example, the first controller 61 may process a clock-embedded digital control signal.

In addition, although one set of clock signals and data signals is used as digital control signals for the pre-regulator circuit 10 and the switched-capacitor circuit 20, a set of clock signals and digital signals may be used as the digital control signals individually for the pre-regulator circuit 10 and the switched-capacitor circuit 20.

The high frequency system 200 may include a receive path that has a low-noise amplifier and a receive filter. In addition, the high frequency system 200 may include a plurality of power amplifiers corresponding to different communication bands.

The tracker module 100 and the high frequency system 200 according to the respective modification examples described above also produce similar effects to the tracker module 100 and the high frequency system 200 according to Exemplary Embodiment 1.

### Exemplary Embodiment 2

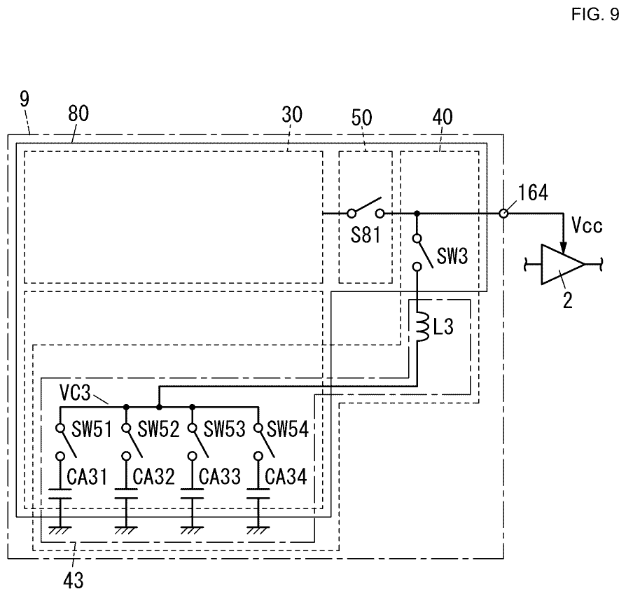

A tracker module 100 according to Exemplary Embodiment 2 differs from the tracker module 100 (see, e.g., FIG. 1) according to Exemplary Embodiment 1 in that as illustrated in FIG. 9, the filter circuit 40 has a one-stage LC series circuit 43. For purposes of this disclosure, it is noted that for the tracker module 100 according to Exemplary Embodiment 2, components similar to those of the tracker module 100 according to Exemplary Embodiment 1 will be denoted by the same reference numerals, and a description thereof will be omitted.

### Configuration

As illustrated in FIG. 9, the filter circuit 40 of Exemplary Embodiment 2 has the one-stage LC series circuit 43, instead of two-stage LC series circuits (first LC series circuit 41 and second LC series circuit 42). The filter circuit 40 of Exemplary Embodiment 2 has the input terminal 141, the output terminal 142, the inductor L0, and the one LC series circuit 43, and the one changeover switch SW3. For purposes of this disclosure, it is noted that for the filter circuit 40 of Exemplary Embodiment 2, a description of a configuration and functions similar to those of the filter circuit 40 of Exemplary Embodiment 1 (see, e.g., FIG. 1) will be omitted.

The LC series circuit 43 includes an inductor L3 and a variable capacitor VC3. The inductor L3 and the variable capacitor VC3 are connected in series between the one end of the inductor L0 and ground. More specifically, one end (first end) of the inductor L3 is connected to the one end (first end) of the inductor L0, another end (second end) of the inductor L3 is connected to one of two electrodes of the variable capacitor VC3, and the other electrode of the two electrodes of the variable capacitor VC3 is connected to ground.

The variable capacitor VC3 includes a plurality of (four in the example of FIG. 9) capacitors CA31 to CA34 and a plurality of switches SW51 to SW54. The plurality of capacitors CA31 to CA34 corresponds one-to-one to the plurality of switches SW51 to SW54, and each of the plurality of capacitors CA31 to CA34 is connected in series to a corresponding switch of the plurality of switches SW51 to SW54. The capacitance of the variable capacitor VC3 is varied by switching ON/OFF of each of the plurality of switches SW51 to SW54.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 of Exemplary Embodiment 2 have one attenuation pole. The frequency of the one attenuation pole is determined by a circuit constant of each of the inductor L3 and the variable capacitor VC3 of the LC series circuit 43.

Similarly to the filter circuit 40 of Exemplary Embodiment 1, the filter circuit 40 of Exemplary Embodiment 2 reduces the amplitude of the spike-like voltage of an output voltage output from the supply modulator 30. That is, by including the filter circuit 40, the power supply circuit 1 can reduce waveform distortion in an output voltage output from the supply modulator 30, so that the power supply circuit 1 can reduce high frequency components in the output voltage described above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 2, the variable capacitor VC3 of the filter circuit 40 is integrated in the IC chip 80. In the IC chip 80, in a plan view of the thickness direction DO of the IC chip 80, the SM switch portion 104 in which the plurality of switches S51 to S54 of the supply modulator 30 is formed is adjacent to the functional element portion 106 in which the variable capacitor VC3 of the filter circuit 40 is formed.

In addition, in the tracker module 100 according to Exemplary Embodiment 2, the inductors L0 and L3 of the filter circuit 40 are disposed on the module laminate 9. More specifically, the inductors L0 and L3 are disposed on the first principal surface 91 of the module laminate 9. Each of the inductors L0 and L3 is a chip inductor. That is, each of the inductors L0 and L3 is a surface-mount type inductor.

### (2) Technical Effects

In the tracker module 100 according to Exemplary Embodiment 2, similarly to Exemplary Embodiment 1 as well, the size of the tracker module 100 can be reduced compared to a case in which the switches SW51 to SW54 of the variable capacitor VC3 are not integrated in the IC chip 80.

### (3) Modification Example of Exemplary Embodiment 2

In the following, a modification example of Exemplary Embodiment 2 will be described.

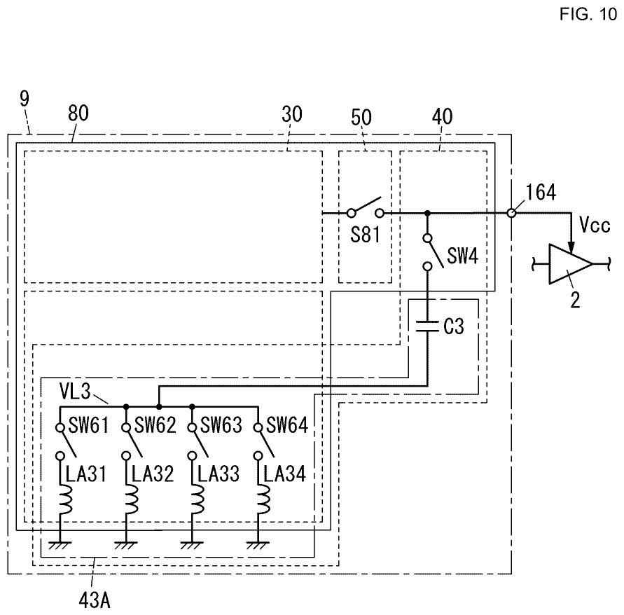

As illustrated in FIG. 10, a tracker module 100 according to the modification example of Exemplary Embodiment 2 differs from the tracker module 100 according to Exemplary Embodiment 2 (see, e.g., FIG. 9) in that the filter circuit 40 has an LC series circuit 43A instead of the LC series circuit 43.

The LC series circuit 43A includes a capacitor C3 and a variable inductor VL3. The capacitor C3 and the variable inductor VL3 are connected in series between the one end of the inductor L0 and ground. More specifically, one end (first end) of the capacitor C3 is connected to the one end (first end) of the inductor L0, another end (second end) of the capacitor C3 is connected to one of two electrodes of the variable inductor VL3, and the other electrode of the two electrodes of the variable inductor VL3 is connected to ground.

The variable inductor VL3 includes a plurality of (four in the example of FIG. 10) inductors LA31 to LA34 and a plurality of switches SW61 to SW64. The plurality of inductors LA31 to LA34 corresponds one-to-one to the plurality of switches SW61 to SW64, and each of the plurality of inductors LA31 to LA34 is connected in series to a corresponding switch of the plurality of switches SW61 to SW64. The inductance of the variable inductor VL3 is changed by switching ON/OFF each of the plurality of switches SW61 to SW64.

In the tracker module 100 according to the modification example of Exemplary Embodiment 2, the variable inductor VL3 of the filter circuit 40 is integrated in the IC chip 80. In the IC chip 80, in a plan view of the thickness direction DO of the IC chip 80, a plurality of SM switch portions 104 in which the plurality of switches SW61 to SW64 of the supply modulator 30 is formed is adjacent to the functional element portion 106 in which the variable inductor VL3 of the filter circuit 40 is formed.

In addition, in the tracker module 100 according to the modification example of Exemplary Embodiment 2, although not illustrated, the inductor L0 and the capacitor C1 of the filter circuit 40 are disposed on the module laminate 9. More specifically, the inductor L0 and the capacitor C1 are disposed on the first principal surface 91 of the module laminate 9. The inductor L0 is a chip inductor, and the capacitor C1 is a chip capacitor. That is, the inductor L0 is a surface-mount type inductor, and the capacitor C1 is a surface-mount type capacitor.

The tracker module 100 according to the modification example described above also produces similar effects to the tracker module 100 according to Exemplary Embodiment 2.

### Exemplary Embodiment 3

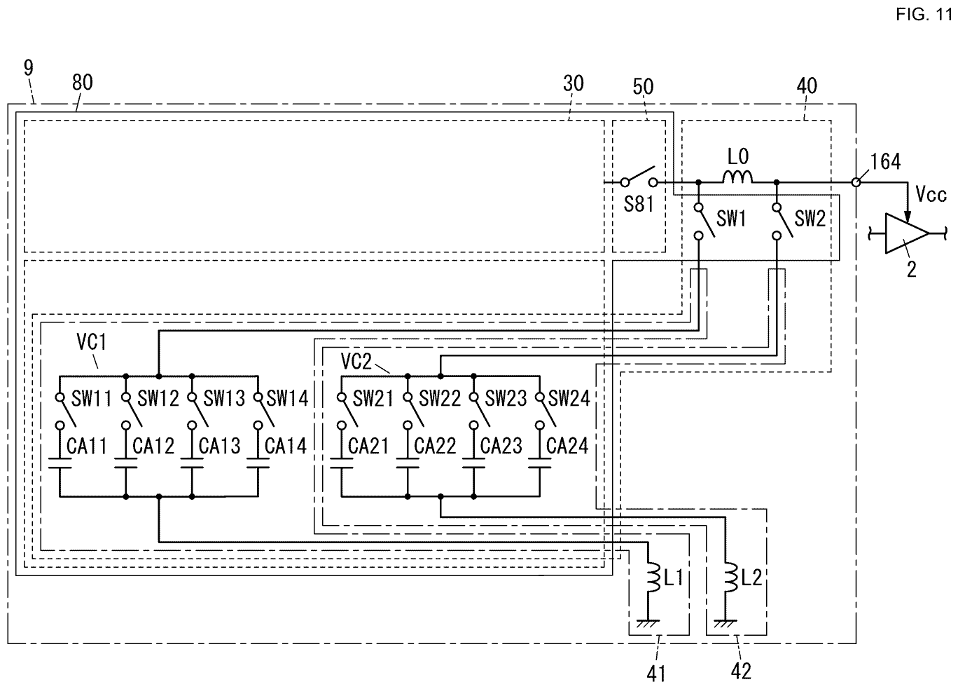

A tracker module 100 according to Exemplary Embodiment 3 differs from the tracker module 100 according to Exemplary Embodiment 1 (see, e.g., FIG. 1) in that the filter circuit 40 has a plurality of the LC series circuits (first LC series circuit 41 and second LC series circuit 42) as illustrated in FIG. 11. For purposes of this disclosure, it is noted that for the tracker module 100 according to Exemplary Embodiment 3, components similar to those of the tracker module 100 according to Exemplary Embodiment 1 will be denoted by the same reference numerals and a description thereof will be omitted.

### Configuration

As illustrated in FIG. 11, the filter circuit 40 of Exemplary Embodiment 3 has the input terminal 141, the output terminal 142, the inductor L0, a plurality of (two in the example of FIG. 11) LC series circuits (first LC series circuit 41 and second LC series circuit 42). For purposes of this disclosure, it is noted that for the filter circuit 40 of Exemplary Embodiment 3, a description of the configuration and the functions similar to those of the filter circuit 40 of Exemplary Embodiment 1 (see, e.g., FIG. 1) will be omitted. The first LC series circuit 41 includes the inductor L1 and the variable capacitor VC1. The inductor L1 and the variable capacitor VC1 are connected in series between the one end of the inductor L0 and ground. More specifically, one end (first end) of the variable capacitor VC1 is connected to the supply modulator 30 via the band select switch circuit 50, and to the one end (first) end of the inductor L0. Another end (second end) of the variable capacitor VC1 is connected to one of the two electrodes of the inductor L1, and the other electrode of the two electrodes of the inductor L1 is connected to ground.

The variable capacitor VC1 includes the plurality of (four in the example of FIG. 11) capacitors CA11 to CA14 and the plurality of switches SW11 to SW14. The plurality of capacitors CA11 to CA14 corresponds one-to-one to the plurality of switches SW11 to SW14, and each of the plurality of capacitors CA11 to CA14 is connected in series to a corresponding switch of the plurality of switches SW11 to SW14. The capacitance of the variable capacitor VC1 is varied by switching ON/OFF of each of the plurality of switches SW11 to SW14.

The second LC series circuit 42 includes the inductor L2 and the variable capacitor VC2. The inductor L2 and the variable capacitor VC2 are connected in series between the other end of the inductor L0 and ground. More specifically, one end (first end) of the variable capacitor VC2 is connected to the other end (second end) of the inductor L0, and another end (second end) of the variable capacitor VC2 is connected to one of two electrodes of the inductor L2 and the other electrode of the two electrodes of the inductor L2 is connected to ground.

The variable capacitor VC2 includes the plurality of (four in the example of FIG. 11) capacitors CA21 to CA24 and the plurality of switches SW21 to SW24. The plurality of capacitors CA21 to C24 corresponds one-to-one to the plurality of switches SW21 to Sw24, and each of the plurality of capacitors CA21 to CA24 is connected in series to a corresponding one of the plurality of switches SW21 to SW24. The capacitance of the variable capacitor VC2 is varied by switching ON/OFF of each of the plurality of switches SW21 to SW24.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 have the two attenuation poles. The frequency of one of the two attenuation poles is determined by the respective circuit constants of the inductor L1 and the variable capacitor VC1 of the first LC series circuit 41. In addition, the frequency of the other of the two attenuation poles is determined by the respective circuit constants of the inductor L2 and the variable capacitor VC2 of the second LC series circuit 42.

The filter circuit 40 reduces the amplitude of the spike-like voltage in the output voltage output from the supply modulator 30. That is, by including the filter circuit 40, the power supply circuit 1 can reduce the waveform distortion in the output voltage output from the supply modulator 30, thereby reducing the radio frequency components in the output voltage mentioned above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 3, the variable capacitors VC1 and VC2 of the filter circuit 40 are integrated in the IC chip 80. In the IC chip 80, in a plan view of the thickness direction DO of the module laminate 9, the SM switch portion 104 where the plurality of switches S51 to S54 of the supply modulator 30 is formed is adjacent to the functional element portion 106 in which the variable capacitors VC1 and VC2 of the filter circuit 40 is formed.

In addition, in the tracker module 100 according to Exemplary Embodiment 3, the inductor L0 and the inductor L1 of the filter circuit 40 are disposed on the module laminate 9. More specifically, the inductor L0 and the inductor L1 are disposed on the first principal surface 91 of the module laminate 9. Each of the inductor L0 and the inductor L1 is a chip inductor. That is, each of the inductor L0 and the inductor L1 is a surface-mount type inductor.

### (2) Technical Effects

In the tracker module 100 according to Exemplary Embodiment 3, the variable capacitors VC1 and VC2 are connected to the supply modulator 30, and the inductors L1 and L2 are connected between the variable capacitors VC1 and VC2 and ground. This can simplify wiring between the inside of the IC chip 80 and the outside of the IC chip 80.

### (3) Modification Example of Exemplary Embodiment 3

In the following, a modification example of Exemplary Embodiment 3 will be described.

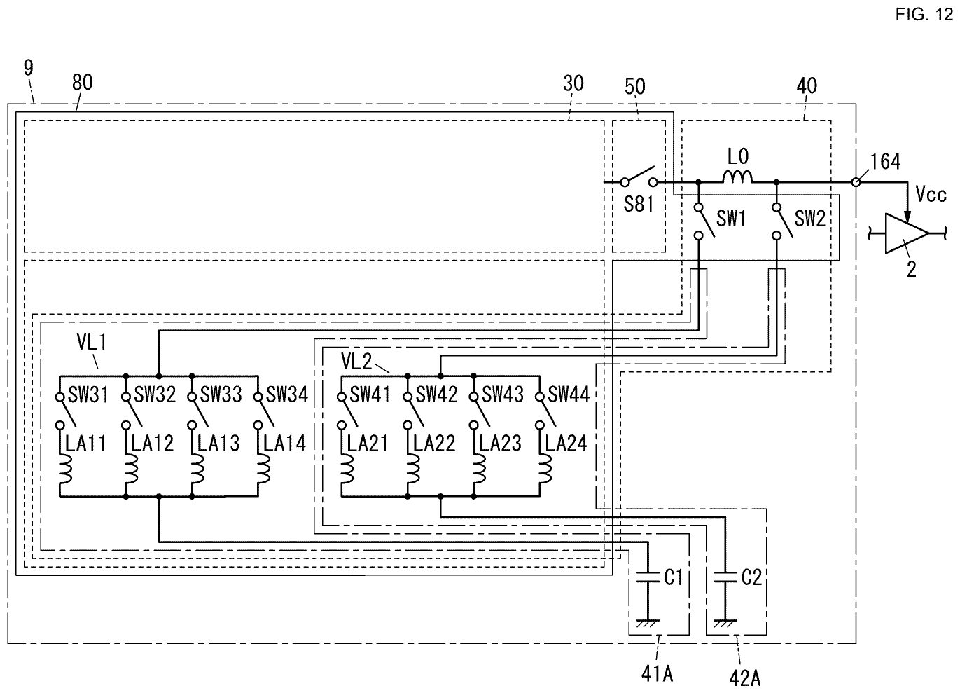

As illustrated in FIG. 12, the tracker module 100 according to the modification example of Exemplary Embodiment 3 differs from the tracker module 100 according to Exemplary Embodiment 3 (see, e.g., FIG. 11) in that the filter circuit 40 has a plurality of (two in the example of FIG. 12) the LC series circuits (first LC series circuit 41A and second LC series circuit 42A), instead of the plurality of LC series circuits (first LC series circuit 41 and second LC series circuit 42).

The first LC series circuit 41A includes the capacitor C1 and the variable inductor VL1. The capacitor C1 and the variable inductor VL1 are connected in series between the one end of the inductor L0 and ground. More specifically, one end (first end) of the variable inductor VL1 is connected to one end (first end) of the inductor L0, another end (second end) of the variable inductor VL1 is connected to one of the two electrodes of the capacitor C1, and the other electrode of the two electrodes of the capacitor C1 is connected to ground.

The variable inductor VL1 includes a plurality of (four in the example of FIG. 12) inductors LA11 to LA14 and a plurality of switches SW31 to SW34. The plurality of inductors LA11 to LA14 corresponds one-to-one to the plurality of switches SW31 to SW34, and each of the plurality of inductors LA11 to LA14 is connected in series to a corresponding switch of the plurality of switches SW31 to Sw34. The inductance of the variable inductor VL1 is varied by switching ON/OFF each of the plurality of switches SW31 to SW34.

The second LC series circuit 42A includes the capacitor C2 and a variable inductor VL2. The capacitor C2 and the variable inductor VL2 are connected in series between the other end of the inductor L0 and ground. More specifically, one end (first end) of the variable inductor VL2 is connected to the other end (second end) of the inductor L0, the other end (second end) of the variable inductor VL2 is connected to the one of two electrodes of the capacitor C2, and the other electrode of the two electrodes of the capacitor C2 is connected to ground.

The variable inductor VL2 includes the plurality of (four in the example of FIG. 12) inductors LA21 to LA 24 and the plurality of switches SW41 to SW44. The plurality of inductors LA21 to lA24 corresponds one-to-one to the plurality of switches SW41 to SW44, and each of the plurality of inductors LA21 to LA24 is connected in series to the corresponding switch of the plurality of switches SW41 to Sw44. The inductance of the variable inductor VL2 is varied by switching ON/OFF each of the plurality of switches SW41 to SW44.

In the tracker module 100 according to the modification example of Exemplary Embodiment 3, the variable inductors VL1 and VL2 of the filter circuit 40 are integrated in the IC chip 80. In the IC chip 80, in a plan view of the thickness direction DO of the IC chip 80, the SM switch portion 104 where the plurality of switches S51 to S54 of the supply modulator 30 is formed is adjacent to the functional element portion 106 in which the variable inductors VL1 and VL2 of the filter circuit 40 is formed.

In addition, in the tracker module 100 according to the modification example of Exemplary Embodiment 3, although not illustrated, the inductor L0 and the capacitors C1 and C2 of the filter circuit 40 are disposed on the module laminate 9. More specifically, the inductor L0 and the capacitors C1 and C2 are disposed on the first principal surface 91 of the module laminate 9. The inductor L0 is a chip inductor, and each of the capacitors C1 and C2 is a chip capacitor. That is, the inductor L0 is a surface-mount type inductor, and each of the capacitors C1 and C2 is a surface-mount type capacitor.

The tracker module 100 according to the modification example described above also produces similar effects to the tracker module 100 according to Exemplary Embodiment 3.

### Exemplary Embodiment 4

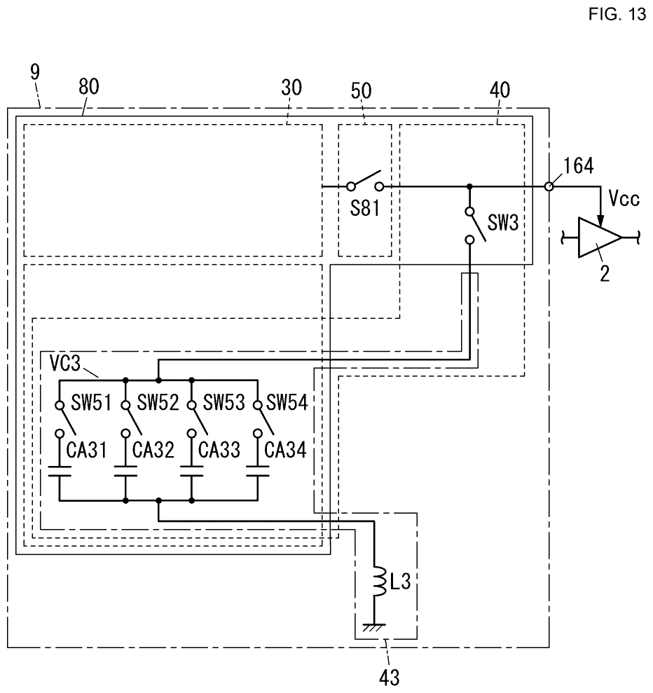

The tracker module 100 according to Exemplary Embodiment 4 differs from the tracker module 100 according to Exemplary Embodiment 3 (see, e.g., FIG. 11) in that as illustrated in FIG. 13, the filter circuit 40 has the one-stage LC series circuit 43A. For purposes of this disclosure, it is noted that for the tracker module 100 according to Exemplary Embodiment 4, components similar to those of the tracker module 100 according to Exemplary Embodiment 3 will be denoted by the same reference numerals and a description thereof will be omitted.

### Configuration

The filter circuit 40 of Exemplary Embodiment 4 has the one-stage LC series circuit 43, instead of the two-stage LC series circuit (first LC series circuit 41 and second LC series circuit 42), as illustrated in FIG. 13. The filter circuit 40 of Exemplary Embodiment 4 has the input terminal 141, the output terminal 142, the inductor L0, and the one LC series circuit 43. For purposes of this disclosure, it is noted that for the filter circuit 40 of Exemplary Embodiment 4, a description of the configuration and the functions similar to those of the filter circuit 40 of Exemplary Embodiment 3 (see, e.g., FIG. 11) will be omitted.

The LC series circuit 43 includes the inductor L3 and the variable capacitor VC3. The inductor L3 and the variable capacitor VC3 are connected in series between the one end of the inductor L0 and ground. More specifically, the one end (first end) of the variable capacitor VC3 is connected to the one end of the inductor L0, the other end (second end) of the variable capacitor VC3 is connected to one of two electrodes of the inductor L3, and the other electrode of the two electrodes of the inductor L3 is connected to ground.

The variable capacitor VC3 includes a plurality of (four in the example of FIG. 13) capacitors CA31 to CA34 and a plurality of switches SW51 to SW54. The plurality of capacitors CA31 to CA34 corresponds one-to-one to the plurality of switches SW51 to SW54, and each of the plurality of capacitors CA31 to CA34 is connected in series to a corresponding switch of the plurality of switches SW51 to SW54. The capacitance of the variable capacitor VC1 is varied by switching ON/OFF of each of the plurality of switches SW51 to SW54.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 of Exemplary Embodiment 4 have the one attenuation pole. The frequency of the one attenuation pole is determined by the circuit constant of each of the inductor L3 and the variable capacitor VC3 of the LC series circuit 43.

Similarly to the filter circuit 40 of Exemplary Embodiment 3, the filter circuit 40 of Exemplary Embodiment 4 reduces the amplitude of the spike-like voltage of an output voltage output from the supply modulator 30. That is, by including the filter circuit 40, the power supply circuit 1 can reduce waveform distortion in an output voltage output from the supply modulator 30, so that the power supply circuit 1 can reduce high frequency components in the output voltage described above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 4, the variable capacitor VC3 of the filter circuit 40 is integrated in the IC chip 80. In the IC chip 80, in a plan view of the thickness direction DO of the module laminate 9, the SM switch portion 104 in which the plurality of switches S51 to S54 of the supply modulator 30 is formed is adjacent to the functional element portion 106 in which the variable capacitor VC3 of the filter circuit 40 is formed.

In the tracker module 100 according to Exemplary Embodiment 4, the inductor L0 and the inductor L1 of the filter circuit 40 are disposed on the module laminate 9. More specifically, the inductor L0 and the inductor L1 are disposed on the first principal surface 91 of the module laminate 9. Each of the inductor L0 and the inductor L1 is a chip inductor. That is, each of the inductor L0 and the inductor L1 is a surface-mount type inductor.

### (2) Technical Effects

In the tracker module 100 according to Exemplary Embodiment 4, similarly to Exemplary Embodiment 3, the variable capacitor VC3 is connected to the supply modulator 30, and the inductor L3 is connected between the variable capacitor VC3 and ground. This can simplify wiring between the inside of the IC chip 80 and the outside of the IC chip 80.

### (3) Modification Example of Exemplary Embodiment 4

In the following, a modification example of Exemplary Embodiment 4 will be described.

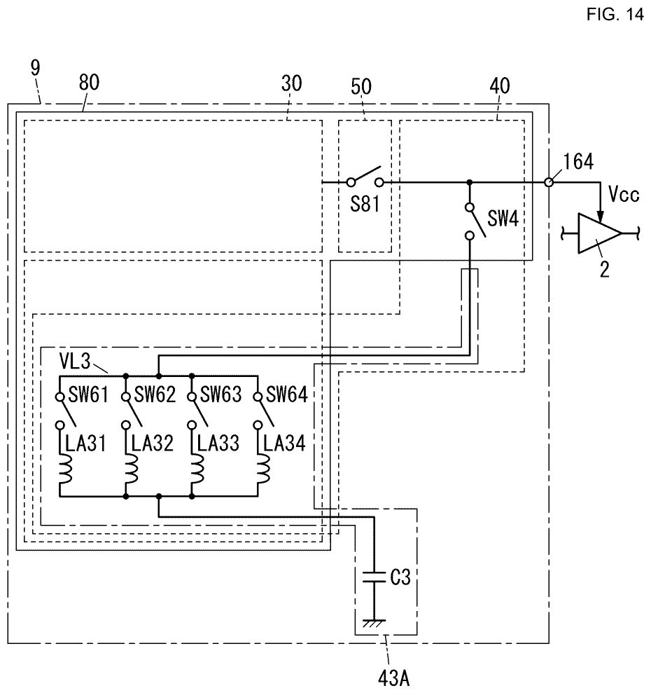

The tracker module 100 according to the modification example of Exemplary Embodiment 4 differs from the tracker module 100 according to Exemplary Embodiment 3 (see, e.g., FIG. 13) in that as illustrated in FIG. 14, the filter circuit 40 has the LC series circuit 43A, instead of the LC series circuit 43.

The LC series circuit 43A includes a capacitor C3 and a variable inductor VL3. The capacitor C3 and the variable inductor VL3 are connected in series between the one end of the inductor L0 and ground. More specifically, one end (first end) of the variable inductor VL3 is connected to the supply modulator 30 with the band select switch circuit 50 interposed therebetween, and is connected to the one end (first end) of the inductor L0. Another end (second end) of the variable inductor VL3 is connected to one of the two electrodes of the capacitor C3, and the other electrode of the two electrodes of the capacitor C3 is connected to ground. That is, the capacitor C3 is connected between the variable inductor VL3 and ground.

The variable inductor VL3 includes the plurality of (four in the example of FIG. 14) inductors LA31 to LA34 and the plurality of switches SW61 to SW64. The plurality of inductors LA31 to LA34 corresponds one-to-one to the plurality of switches SW61 to SW64, and each of the plurality of inductors LA31 to LA34 is connected in series to the corresponding switch of the plurality of switches SW61 to SW64. The inductance of the variable inductor VL3 is varied by switching ON/OFF each of the plurality of switches SW61 to SW64.

In the tracker module 100 according to the modification example of Exemplary Embodiment 4, the variable inductor VL3 of the filter circuit 40 is integrated in the IC chip 80. In the IC chip 80, in a plan view of the thickness direction DO of the module laminate 9, the SM switch portion 104 in which the plurality of switches S51 to S54 of the supply modulator 30 is formed is adjacent to the functional element portion 106 in which the variable inductor VL3 of the filter circuit 40 is formed.

In addition, in the tracker module 100 according to the modification example of Exemplary Embodiment 4, although not illustrated, the inductor L0 and the capacitor C3 of the filter circuit 40 are disposed on the module laminate 9. More specifically, the inductor L0 and the capacitor C3 are disposed on the first principal surface 91 of the module laminate 9. The inductor L0 is a chip inductor, and the capacitor C3 is a chip capacitor. That is, the inductor L0 is a surface-mount type inductor, and the capacitor C3 is a surface-mount type capacitor.

The tracker module 100 according to the modification example described above also produces similar effects to the tracker module 100 according to Exemplary Embodiment 4.

### Exemplary Embodiment 5

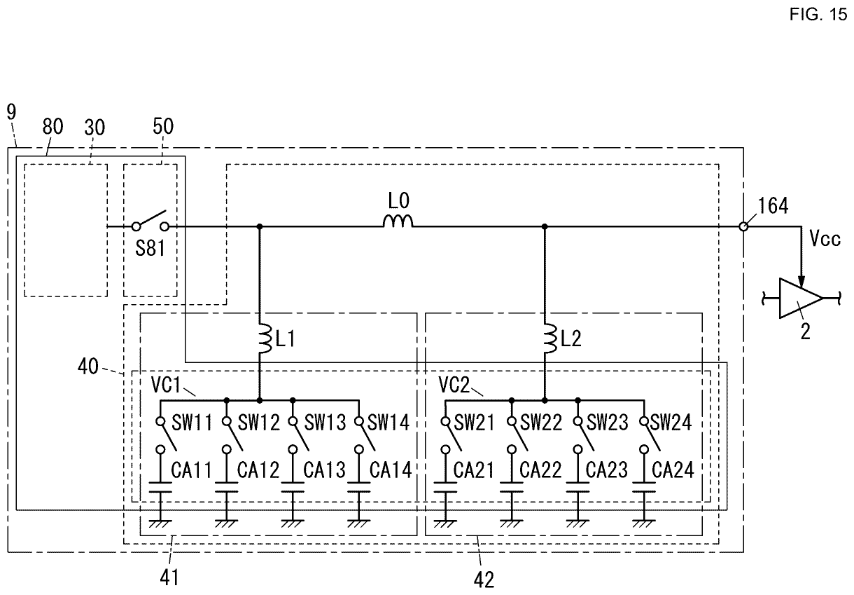

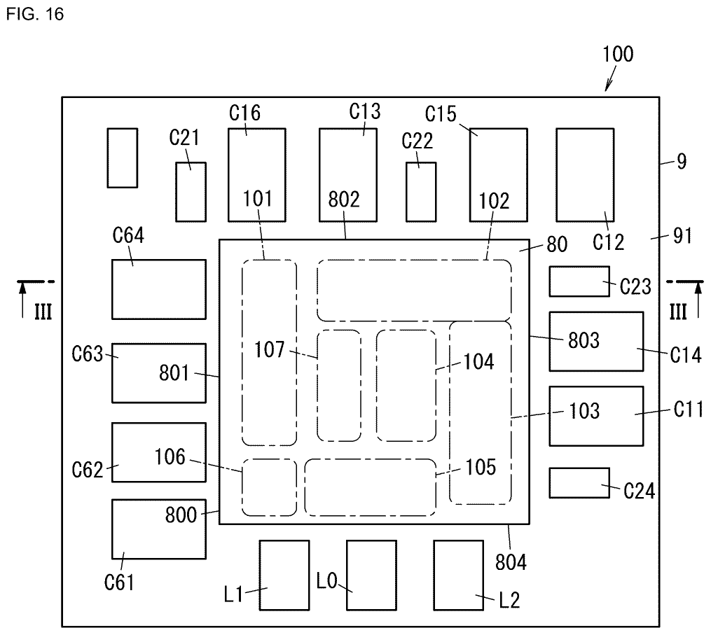

The tracker module 100 according to Exemplary Embodiment 5 differs from the tracker module 100 according to Exemplary Embodiment 1 (see, e.g., FIG. 1) in that as illustrated in FIG. 15, the variable capacitors VC1 and VC2 of the filter circuit 40 are adjacent to the plurality of switches S81 to s84 of the band select switch circuit 50. For purposes of this disclosure, it is noted that for the tracker module 100 according to Exemplary Embodiment 5, components similar to those of the tracker module 100 according to Exemplary Embodiment 1 will be denoted by the same reference numerals, and will not be described.

### Configuration

As illustrated in FIG. 15, the filter circuit 40 of Exemplary Embodiment 5 includes the input terminal 141, the output terminal 142, the inductor L0, and the plurality of (two in the example of FIG. 15) LC series circuits (first LC series circuit 41 and second LC series circuit 42). For purposes of this disclosure, it is noted that for the filter circuit 40 of Exemplary Embodiment 5, a description of the configuration and the functions similar to those of the filter circuit 40 of Exemplary Embodiment 1 (see, e.g., FIG. 1) will be omitted.

The first LC series circuit 41 includes the inductor L1 and the variable capacitor VC1. The inductor L1 and the variable capacitor VC1 are connected in series between the one end of the inductor L0 and ground. More specifically, the one end (first end) of the variable capacitor VC1 is connected to the supply modulator 30 with the band select switch circuit 50 interposed therebetween, and is connected to the one end (first end) of the inductor L0. The other end (second end) of the variable capacitor VC1 is connected to one of the two electrodes of the inductor L1, and the other electrode of the two electrodes of the inductor L1 is connected to ground. That is, the inductor L1 is connected between the variable capacitor VC1 and ground.

The variable capacitor VC1 includes the plurality of (four in the example of FIG. 15) capacitors CA11 to CA14 and the plurality of switches SW11 to SW14. The plurality of capacitors CA11 to CA14 corresponds one-to-one to the plurality of switches SW11 to SW14, and each of the plurality of capacitors CA11 to CA14 is connected in series to a corresponding switch of the plurality of switches SW11 to SW14. The capacitance of the variable capacitor VC1 is varied by switching ON/OFF of each of the plurality of switches SW11 to SW14.

The second LC series circuit 42 includes the inductor L2 and the variable capacitor VC2. The inductor L2 and the variable capacitor VC2 are connected in series between the other end of the inductor L0 and ground. More specifically, the one end (first end) of the variable capacitor VC2 is connected to the supply modulator 30 with the band select switch circuit 50 interposed therebetween, and is connected to the other end (second end) of the inductor L0. The other end (second end) of the variable capacitor VC2 is connected to the one of the two electrodes of the inductor L2 and the other electrode of the two electrodes of the inductor L2 is connected to ground. That is, the inductor L2 is connected between the variable capacitor VC2 and ground.

The variable capacitor VC2 includes the plurality of (four in the example of FIG. 15) capacitors CA21 to CA24 and the plurality of switches SW21 to SW24. The plurality of capacitors CA21 to CA24 corresponds one-to-one to the plurality of switches SW21 to SW24, and each of the plurality of capacitors CA21 to CA24 is connected in series to a corresponding switch of the plurality of switches SW21 to SW24. The capacitance of the variable capacitor VC2 is varied by switching ON/OFF of each of the plurality of switches SW21 to SW24.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 have the two attenuation poles. The frequency of one of the two attenuation poles is determined by the respective circuit constants of the inductor L1 and the variable capacitor VC1 of the first LC series circuit 41. In addition, the frequency of the other of the two attenuation poles is determined by the respective circuit constants of the inductor L2 and the variable capacitor VC2 of the second LC series circuit 42.

The filter circuit 40 reduces the amplitude of the spike-like voltage in the output voltage output from the supply modulator 30. That is, by including the filter circuit 40, the power supply circuit 1 can reduce the waveform distortion in the output voltage output from the supply modulator 30, thereby reducing the radio frequency components in the output voltage mentioned above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 5, the variable capacitors VC1 and VC2 of the filter circuit 40 are integrated in the IC chip 80. In the IC chip 80, in a plan view of the thickness direction DO of the module laminate 9, the BS switch portion 105 in which the plurality of switches S81 to S84 of the band select switch circuit 50 is formed is adjacent to the functional element portion 106 in which the variable capacitors VC1 and VC2 of the filter circuit 40 are formed.

Furthermore, in the IC chip 80, in a plan view of the thickness direction DO of the module laminate 9, the SC switch portion 102 in which the plurality of switches S11 to S14 and S21 to S24 of the switched-capacitor circuit 20 is formed, the SC switch portion 103 in which the plurality of switches S31 to S34 and S41 to S44 is formed, and the functional element portion 106 in which the variable capacitors VC1 and VC2 of the filter circuit 40 are separated from each other.

In the tracker module 100 according to Exemplary Embodiment 5, the inductor L0 and the inductor L1 of the filter circuit 40 are disposed on the module laminate 9. More specifically, the inductor L0 and the inductor L1 are disposed on the first principal surface 91 of the module laminate 9. Each of the inductor L0 and the inductor L1 is a chip inductor. That is, each of the inductor L0 and the inductor L1 is a surface-mount type inductor.

### (2) Technical Effects

In the tracker module 100 according to Exemplary Embodiment 5, the switches SW11 to SW14 and SW21 to SW24 of the variable capacitors (variable reactance elements) VC1 and VC2 in the filter circuit 40 are separated from at least one of the switches S11 to S14, S21 to S24, S31 to S34, and S41 to S44 in the switched-capacitor circuit 20. This configuration the separation of the switches SW11 to SW14 and SW21 to SW24 of the variable capacitors VC1 and VC2 in the filter circuit 40 from the switches S11 to S14, S21 to S24, S31 to S34, and S41 to S44 of the switched-capacitor circuit 20 which are prone to generate heat. Therefore, in the filter circuit 40, influence of heat from the switches S11 to S14, S21 to S24, S31 to S34, and S41 to S44 of the switched-capacitor circuit 20 can be reduced.

In the tracker module 100 according to Exemplary Embodiment 5, the switches SW11 to SW14 and SW21 to SW24 of the variable capacitors (variable reactance elements) VC1 and VC2 in the filter circuit 40 are adjacent to the plurality of switches S81 to S84 of the band select switch circuit 50. This can shorten a wiring length between the band select switch circuit 50 and the filter circuit 40.

### (3) Modification Example of Exemplary Embodiment 5

In the following, a modification example of Exemplary Embodiment 5 will be described.

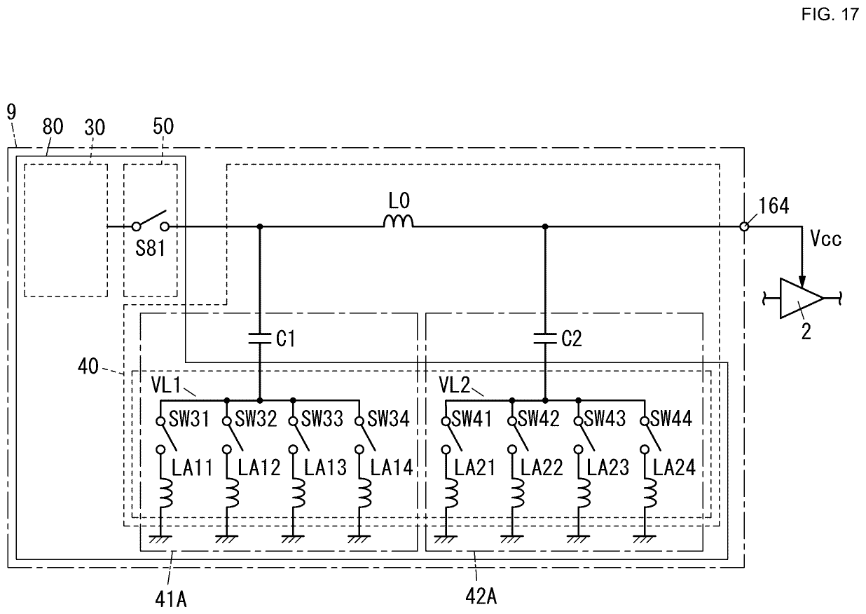

The tracker module 100 according to the modification example of Exemplary Embodiment 5 differs from the tracker module 100 according to Exemplary Embodiment 5 (see, e.g., FIG. 15) in that as illustrated in FIG. 17, the filter circuit 40 has the plurality of (two in the example of FIG. 17) LC series circuits (first LC series circuit 41A and second LC series circuit 42A), instead of the plurality of LC series circuits (first LC series circuit 41 and second LC series circuit 42).

The first LC series circuit 41A includes the capacitor C1 and the variable inductor VL1. The capacitor C1 and the variable inductor VL1 are connected in series between the one end of the inductor L0 and ground. More specifically, the one end of the capacitor C1 (first end) is connected to the one end (first end) of the inductor L0, and the other end (second end) of the capacitor C1 is connected to the one of the two electrodes of the variable inductor VL1, and the other electrode of the two electrodes of the variable inductor VL1 is connected to ground.

The variable inductor VL1 includes the plurality of (four in the example of FIG. 17) inductors LA21 to LA24 and the plurality of switches SW31 to SW34. The plurality of inductors LA21 to LA24 corresponds one-to-one to the plurality of switches SW31 to Sw34, and each of the plurality of inductors LA21 to LA24 is connected in series to the corresponding switch of the plurality of switches SW31 to SW34. The inductance of the variable inductor VL1 is varied by switching ON/OFF each of the plurality of switches SW31 to SW34.

The second LC series circuit 42A includes the capacitor C2 and the variable inductor VL2. The capacitor C2 and the variable inductor VL2 are connected in series between the other end of the inductor L0 and ground. More specifically, the one end (first end) of the capacitor C2 is connected to the other end (second end) of the inductor L0, the other end (second end) of the capacitor C2 is connected to the one of two electrodes of the variable inductor VL2, and the other electrode of the two electrodes of the variable inductor VL2 is connected to ground.

The variable inductor VL2 includes the plurality of (four in the example of FIG. 17) inductors LA21 to LA 24 and the plurality of switches SW41 to SW44. The plurality of inductors LA21 to lA24 corresponds one-to-one to the plurality of switches SW41 to SW44, and each of the plurality of inductors LA21 to LA24 is connected in series to the corresponding switch of the plurality of switches SW41 to Sw44. The inductance of the variable inductor VL2 is varied by switching ON/OFF each of the plurality of switches SW41 to SW44.

In the tracker module 100 according to the modification example of Exemplary Embodiment 5, the variable inductors VL1 and VL2 of the filter circuit 40 are integrated in the IC chip 80. In the IC chip 80, in a plan view of the thickness direction DO of the module laminate 9, the BS switch portion 105 in which the plurality of switches S81 to S84 of the band select switch circuit 50 is formed is adjacent to the functional element portion 106 in which the variable inductors VL1 and VL2 of the filter circuit 40 is formed.

In addition, in the tracker module 100 according to the modification example of Exemplary Embodiment 5, although not illustrated, the inductor L0 and the capacitors C1 and C2 of the filter circuit 40 are disposed on the module laminate 9. More specifically, the inductor L0 and the capacitors C1 and C2 are disposed on the first principal surface 91 of the module laminate 9. The inductor L0 is a chip inductor, and each of the capacitors C1 and C2 is a chip capacitor. That is, the inductor L0 is a surface-mount type inductor, and each of the capacitors C1 and C2 is a surface-mount type capacitor.

The tracker module 100 according to the modification example described above also produces similar effects to the tracker module 100 according to Exemplary Embodiment 5.

### Exemplary Embodiment 6

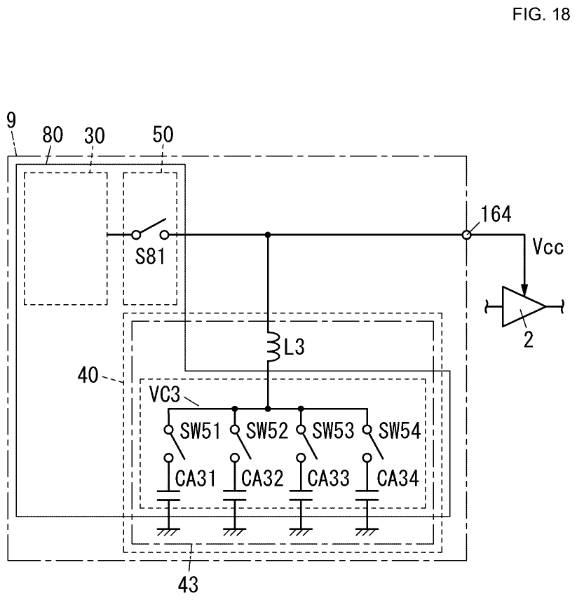

The tracker module 100 according to Exemplary Embodiment 6 differs from the tracker module 100 according to Exemplary Embodiment 5 (see, e.g., FIG. 15) in that as illustrated in FIG. 18, the filter circuit 40 has the one-stage LC series circuit 43. For purposes of this disclosure, it is noted that for the tracker module 100 according to Exemplary Embodiment 6, components similar to those of the tracker module 100 according to Exemplary Embodiment 5 will be denoted by the same reference numerals and a description thereof will be omitted.

### Configuration

The filter circuit 40 of Exemplary Embodiment 6 has the one-stage LC series circuit 43, instead of the two-stage LC series circuit (first LC series circuit 41 and second LC series circuit 42), as illustrated in FIG. 18. The filter circuit 40 of Exemplary Embodiment 6 has the input terminal 141, the output terminal 142, the inductor L0, and the one LC series circuit 43. For purposes of this disclosure, it is noted that for the filter circuit 40 of Exemplary Embodiment 6, a description of the configuration and the functions similar to those of the filter circuit 40 of Exemplary Embodiment 5 (see, e.g., FIG. 15) will be omitted.

The LC series circuit 43 includes the inductor L3 and the variable capacitor VC3. The inductor L3 and the variable capacitor VC3 are connected in series between the one end of the inductor L0 and ground. More specifically, the one end (first end) of the inductor L3 is connected to the supply modulator 30 with the band select switch circuit 50 interposed therebetween, and is connected to the one end (first end) of the inductor L0. The other end (second end) of the inductor L3 is connected to the one of the two electrodes of the variable capacitor VC3 and the other electrode of the two electrodes of the variable capacitor VC3 is connected to ground. That is, the variable capacitor VC3 is connected between the inductor L3 and ground.

The variable capacitor VC3 includes a plurality of (four in the example of FIG. 18) capacitors CA31 to CA34 and a plurality of switches SW51 to SW54. The plurality of capacitors CA31 to CA34 corresponds one-to-one to the plurality of switches SW51 to SW54, and each of the plurality of capacitors CA31 to CA34 is connected in series to a corresponding switch of the plurality of switches SW51 to SW54. The capacitance of the variable capacitor VC3 is varied by switching ON/OFF of each of the plurality of switches SW51 to SW54.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 of Exemplary Embodiment 6 have the one attenuation pole. The frequency of the one attenuation pole is determined by the circuit constant of each of the inductor L3 and the variable capacitor VC3 of the LC series circuit 43.

Similarly to the filter circuit 40 of Exemplary Embodiment 1, the filter circuit 40 of Exemplary Embodiment 6 reduces the amplitude of the spike-like voltage of an output voltage output from the supply modulator 30. That is, by including the filter circuit 40, the power supply circuit 1 can reduce waveform distortion in an output voltage output from the supply modulator 30, so that the power supply circuit 1 can reduce high frequency components in the output voltage described above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 6, the variable capacitor VC3 of the filter circuit 40 is integrated in the IC chip 80. In the IC chip 80, in a plan view of the thickness direction DO of the module laminate 9, the BS switch portion 105 in which the plurality of switches S81 to S84 of the band select switch circuit 50 is formed is adjacent to the functional element portion 106 in which the variable capacitor VC3 of the filter circuit 40 is formed.

In addition, in the tracker module 100 according to Exemplary Embodiment 6, the inductors L0 and L1 of the filter circuit 40 are disposed on the module laminate 9. More specifically, the inductors L0 and L1 are disposed on the first principal surface 91 of the module laminate 9. Each of the inductors L0 and L1 is a chip inductor. That is, each of the inductors L0 and L1 is a surface-mount type inductor.
(2) Technical Effects

In the tracker module 100 according to Exemplary Embodiment 6 as well, similarly to Exemplary Embodiment 5, the switches SW51 to SW54 of the variable capacitor VC3 in the filter circuit 40 can be separated from the switches S11 to S14, S21 to S24, S31 to S34, and S41 to S44 of the switched-capacitor circuit 20 which are prone to generate heat. Therefore, in the filter circuit 40, the influence of heat from the switches S11 to S14, S21 to S24, S31 to S34, and S41 to S44 of the switched-capacitor circuit 20 can be reduced.

In the tracker module 100 according to Exemplary Embodiment 6 as well, similarly to Exemplary Embodiment 5, the wiring length between the band select switch circuit 50 and the filter circuit 40 can also be shortened.

### (3) Modification Example of Exemplary Embodiment 6

In the following, a modification example of Exemplary Embodiment 6 will be described.

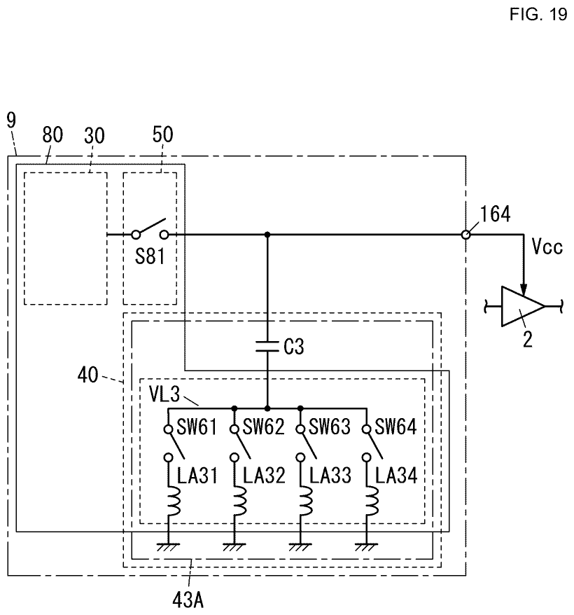

The tracker module 100 according to the modification example of Exemplary Embodiment 6 differs from the tracker module 100 according to Exemplary Embodiment 6 (see, e.g., FIG. 18) in that as illustrated in FIG. 19, the filter circuit 40 has the LC series circuit 43A, instead of the LC series circuit 43.

The LC series circuit 43A includes a capacitor C3 and a variable inductor VL3. The capacitor C3 and the variable inductor VL3 are connected in series between the one end of the inductor L0 and ground. More specifically, the one end (first end) of the capacitor C3 is connected to the one end (first end) of the inductor L0, the other end (second end) of the capacitor C3 is connected to the one of the two electrodes of the variable inductor VL3, and the other electrode of the two electrodes of the variable inductor VL3 is connected to ground.

The variable inductor VL3 includes the plurality of (four in the example of FIG. 19) inductors LA31 to LA34 and the plurality of switches SW61 to SW64. The plurality of inductors LA31 to LA34 corresponds one-to-one to the plurality of switches SW61 to SW64, and each of the plurality of inductors LA31 to LA34 is connected in series to the corresponding switch of the plurality of switches SW61 to SW64. The inductance of the variable inductor VL3 is varied by switching ON/OFF each of the plurality of switches SW61 to SW64.

In the tracker module 100 according to the modification example of Exemplary Embodiment 6, the variable inductor VL3 of the filter circuit 40 is integrated in the IC chip 80. In the IC chip 80, in a plan view of the thickness direction DO of the module laminate 9, the SM switch portion 104 in which the plurality of switches S51 to S54 of the supply modulator 30 is formed is adjacent to the functional element portion 106 in which the variable inductor VL3 of the filter circuit 40 is formed.

In addition, in the tracker module 100 according to the modification example of Exemplary Embodiment 6, although not illustrated, the inductor L0 and the capacitor C1 of the filter circuit 40 are disposed on the module laminate 9. More specifically, the inductor L0 and the capacitor C1 are disposed on the first principal surface 91 of the module laminate 9. The inductor L0 is a chip inductor, and the capacitor C1 is a chip capacitor. That is, the inductor L0 is a surface-mount type inductor, and the capacitor C1 is a surface-mount type capacitor.

The tracker module 100 according to the modification example described above also produces similar effects to the tracker module 100 according to Exemplary Embodiment 6.

### Exemplary Embodiment 7

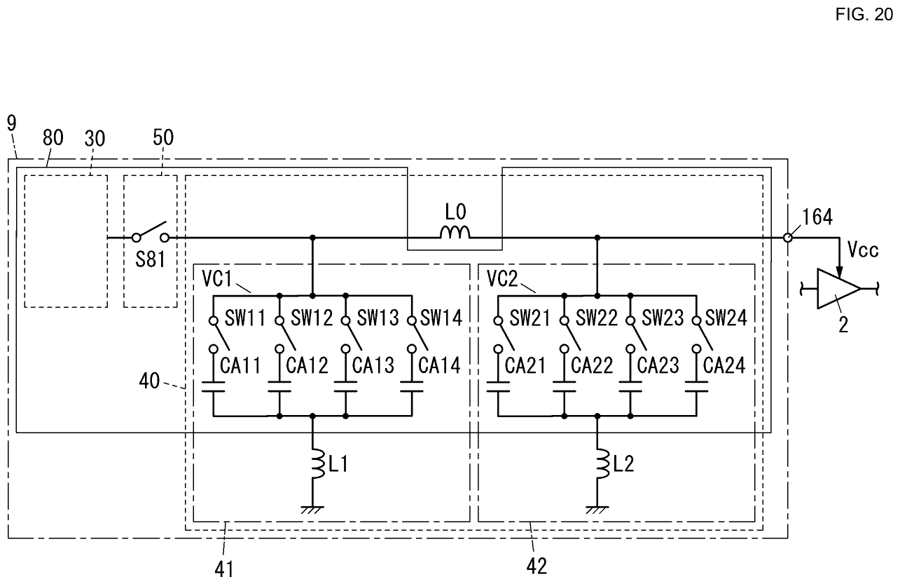

The tracker module 100 according to Exemplary Embodiment 7 differs from the tracker module 100 according to Exemplary Embodiment 5 (see, e.g., FIG. 15) in that the filter circuit 40 has the plurality of LC series circuits (first LC series circuit 41 and second LC series circuit 42) as illustrated in FIG. 20. For purposes of this disclosure, it is noted that for the tracker module 100 according to Exemplary Embodiment 7, components similar to those of the tracker module 100 according to Exemplary Embodiment 5 will be denoted by the same reference numerals and a description thereof will be omitted.

### Configuration

As illustrated in FIG. 20, the filter circuit 40 of Exemplary Embodiment 7 has the input terminal 141, the output terminal 142, the inductor L0, and the plurality of (two in the example of FIG. 20) LC series circuits (first LC series circuit 41 and second LC series circuit 42). For purposes of this disclosure, it is noted that for the filter circuit 40 of Exemplary Embodiment 7, a description of the configuration and the functions similar to those of the filter circuit 40 of Exemplary Embodiment 5 (see, e.g., FIG. 15) will be omitted.

The first LC series circuit 41 includes the inductor L1 and the variable capacitor VC1. The inductor L1 and the variable capacitor VC1 are connected in series between the one end of the inductor L0 and ground. More specifically, the one end (first end) of the variable capacitor VC1 is connected to the one end (first end) of the inductor L0, the other end (second end) of the variable capacitor VC1 is connected to the one of the two electrodes of the inductor L1, and the other electrode of the two electrodes of the inductor L1 is connected to ground.

The variable capacitor VC1 includes the plurality of (four in the example of FIG. 20) capacitors CA11 to CA14 and the plurality of switches SW11 to SW14. The plurality of capacitors CA11 to CA14 corresponds one-to-one to the plurality of switches SW11 to SW14, and each of the plurality of capacitors CA11 to CA14 is connected in series to a corresponding switch of the plurality of switches SW11 to SW14. The capacitance of the variable capacitor VC1 is varied by switching ON/OFF of each of the plurality of switches SW11 to SW14.

The second LC series circuit 42 includes the inductor L2 and the variable capacitor VC2. The inductor L2 and the variable capacitor VC2 are connected in series between the other end of the inductor L0 and ground. More specifically, the one end (first end) of the variable capacitor VC2 is connected to the other end (second end) of the inductor L0, and the other end (second end) of the variable capacitor VC2 is connected to the one of the two electrodes of the inductor L2 and the other electrode of the two electrodes of the inductor L2 is connected to ground.

The variable capacitor VC2 includes the plurality of (four in the example of FIG. 20) capacitors CA21 to CA24 and the plurality of switches SW21 to SW24. The plurality of capacitors CA21 to CA24 corresponds one-to-one to the plurality of switches SW21 to SW24, and each of the plurality of capacitors CA21 to CA24 is connected in series to a corresponding switch of the plurality of switches SW21 to SW24. The capacitance of the variable capacitor VC2 is varied by switching ON/OFF of each of the plurality of switches SW21 to SW24.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 have the two attenuation poles. The frequency of one of the two attenuation poles is determined by the respective circuit constants of the inductor L1 and the variable capacitor VC1 of the first LC series circuit 41. In addition, the frequency of the other of the two attenuation poles is determined by the respective circuit constants of the inductor L2 and the variable capacitor VC2 of the second LC series circuit 42.

The filter circuit 40 reduces the amplitude of the spike-like voltage in the output voltage output from the supply modulator 30. That is, by including the filter circuit 40, the power supply circuit 1 can reduce the waveform distortion in the output voltage output from the supply modulator 30, thereby reducing the radio frequency components in the output voltage mentioned above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 7, the variable capacitors VC1 and VC2 of the filter circuit 40 are integrated in the IC chip 80. In the IC chip 80, in a plan view of the thickness direction DO of the module laminate 9, the BS switch portion 105 in which the plurality of switches S81 to S84 of the band select switch circuit 50 is formed is adjacent to the functional element portion 106 in which the variable capacitors VC1 and VC2 of the filter circuit 40 are formed.

In the tracker module 100 according to Exemplary Embodiment 7, the inductor L0 and the inductor L1 of the filter circuit 40 are disposed on the module laminate 9. More specifically, the inductor L0 and the inductor L1 are disposed on the first principal surface 91 of the module laminate 9. Each of the inductor L0 and the inductor L1 is a chip inductor. That is, each of the inductor L0 and the inductor L1 is a surface-mount type inductor.

### (2) Technical Effects

In the tracker module 100 according to Exemplary Embodiment 7, the variable capacitors VC1 and VC2 are connected to the supply modulator 30, and the inductors L1 and L2 are connected between the variable capacitors VC1 and VC2 and ground. This can simplify wiring between the inside of the IC chip 80 and the outside of the IC chip 80.

### (3) Modification Example of Exemplary Embodiment 7

In the following, a modification example of Exemplary Embodiment 7 will be described.

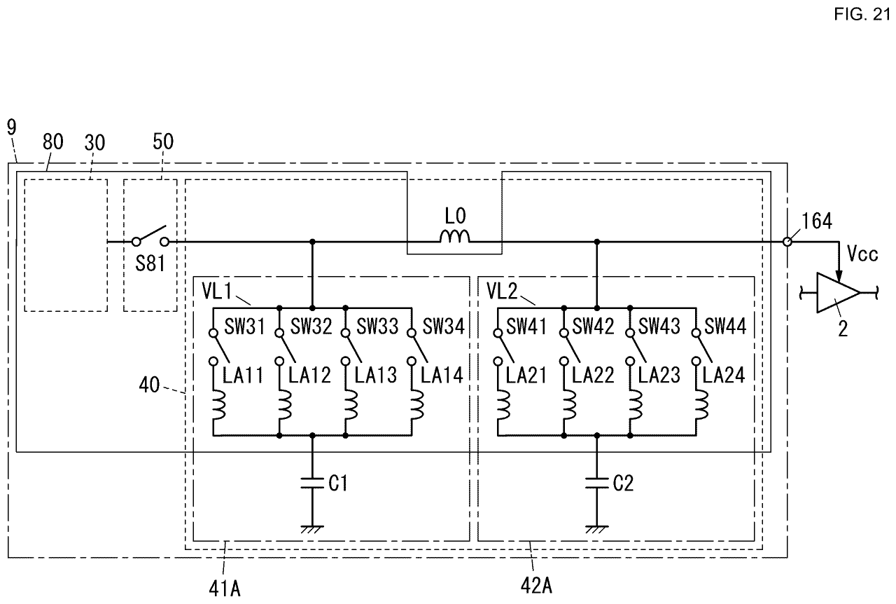

The tracker module 100 according to the modification example of Exemplary Embodiment 7 differs from the tracker module 100 according to Exemplary Embodiment 7 (see, e.g., FIG. 18) in that as illustrated in FIG. 21, the filter circuit 40 has a DTL, instead of a DTC.

The tracker module 100 according to the modification example of Exemplary Embodiment 7 differs from the tracker module 100 according to Exemplary Embodiment 7 (see, e.g., FIG. 20) in that as illustrated in FIG. 21, the filter circuit 40 has the plurality of (two in the example of FIG. 21) LC series circuits (first LC series circuit 41A and second LC series circuit 42A), instead of the plurality of LC series circuits (first LC series circuit 41 and second LC series circuit 42).

The first LC series circuit 41A includes the capacitor C1 and a variable inductor VL1. The capacitor C1 and the variable inductor VL1 are connected in series between the one end of the inductor L0 and ground. More specifically, the one end (first end) of the variable inductor VL1 is connected to the one end (first end) of the inductor L0, other end (second end) of the variable inductor VL1 is connected to the one of the two electrodes of the capacitor C1, and the other electrode of the two electrodes of the capacitor C1 is connected to ground.

The variable inductor VL1 includes a plurality of (four in the example of FIG. 21) inductors LA11 to LA14 and a plurality of switches SW31 to SW34. The plurality of inductors LA11 to LA14 corresponds one-to-one to the plurality of switches SW31 to SW34, and each of the plurality of inductors LA11 to LA14 is connected in series to a corresponding switch of the plurality of switches SW31 to Sw34. The inductance of the variable inductor VL1 is varied by switching ON/OFF each of the plurality of switches SW31 to SW34.

The second LC series circuit 42A includes the capacitor C2 and the variable inductor VL2. The capacitor C2 and the variable inductor VL2 are connected in series between the other end of the inductor L0 and ground. More specifically, the one end (first end) of the variable inductor VL2 is connected to the other end (second end) of the inductor L0, the other end (second end) of the variable inductor VL2 is connected to the one of two electrodes of the capacitor C2, and the other electrode of the two electrodes of the capacitor C2 is connected to ground.

The variable inductor VL2 includes the plurality of (four in the example of FIG. 21) inductors LA21 to LA 24 and the plurality of switches SW41 to SW44. The plurality of inductors LA21 to lA24 corresponds one-to-one to the plurality of switches SW41 to SW44, and each of the plurality of inductors LA21 to LA24 is connected in series to the corresponding switch of the plurality of switches SW41 to Sw44. The inductance of the variable inductor VL2 is varied by switching ON/OFF each of the plurality of switches SW41 to SW44.

In the tracker module 100 according to the modification example of Exemplary Embodiment 7, the variable inductors VL1 and VL2 of the filter circuit 40 are integrated in the IC chip 80. In the IC chip 80, in a plan view of the thickness direction DO of the module laminate 9, the BS switch portion 105 in which the plurality of switches S81 to S84 of the band select switch circuit 50 is formed is adjacent to the functional element portion 106 in which the variable inductors VL1 and VL2 of the filter circuit 40 is formed.

In addition, in the tracker module 100 according to the modification example of Exemplary Embodiment 7, although not illustrated, the inductor L0 and the capacitors C1 and C2 of the filter circuit 40 are disposed on the module laminate 9. More specifically, the inductor L0 and the capacitors C1 and C2 are disposed on the first principal surface 91 of the module laminate 9. The inductor L0 is a chip inductor, and each of the capacitors C1 and C2 is a chip capacitor. That is, the inductor L0 is a surface-mount type inductor, and each of the capacitors C1 and C2 is a surface-mount type capacitor.

The tracker module 100 according to the modification example described above also produces similar effects to the tracker module 100 according to Exemplary Embodiment 7.

### Exemplary Embodiment 8

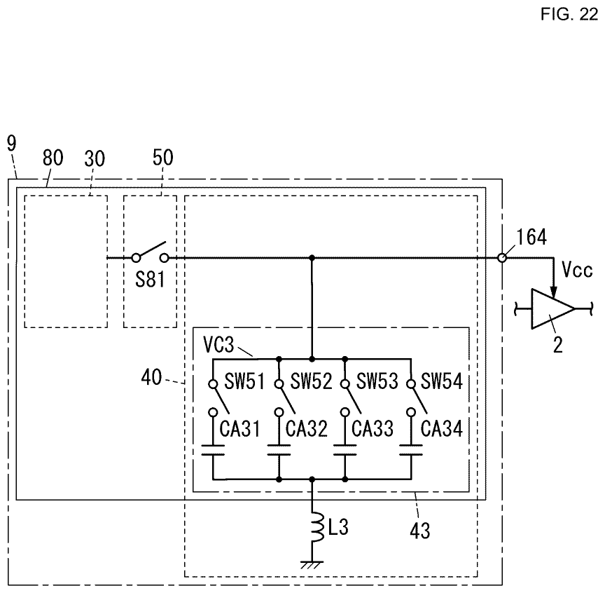

The tracker module 100 according to Exemplary Embodiment 8 differs from the tracker module 100 according to Exemplary Embodiment 7 (see, e.g., FIG. 21) in that as illustrated in FIG. 22, the filter circuit 40 has the one-stage LC series circuit 43. For purposes of this disclosure, it is noted that for the tracker module 100 according to Exemplary Embodiment 8, components similar to those of the tracker module 100 according to Exemplary Embodiment 7 will be denoted by the same reference numerals and a description thereof will be omitted.

### Configuration

The filter circuit 40 of Exemplary Embodiment 8 has the one-stage LC series circuit 43 instead of the two-stage LC series circuit (first LC series circuit 41 and second LC series circuit 42), as illustrated in FIG. 22. The filter circuit 40 of Exemplary Embodiment 8 has the input terminal 141, the output terminal 142, the inductor L0, and the one LC series circuit 43. For purposes of this disclosure, it is noted that for the filter circuit 40 of Exemplary Embodiment 8, a description of the configuration and the functions similar to those of the filter circuit 40 of Exemplary Embodiment 7 (see, e.g., FIG. 22) will be omitted.

The LC series circuit 43 includes the inductor L3 and the variable capacitor VC3. The inductor L3 and the variable capacitor VC3 are connected in series between the one end of the inductor L0 and ground. More specifically, the one end (first end) of the variable capacitor VC3 is connected to the one end (first end) of the inductor L0, the other end (second end) of the variable capacitor VC3 is connected to the one of the two electrodes of the inductor L3, and the other electrode of the two electrodes of the inductor L3 is connected to ground.

The variable capacitor VC3 includes a plurality of (four in the example of FIG. 22) capacitors CA31 to CA34 and a plurality of switches SW51 to SW54. The plurality of capacitors CA31 to CA34 corresponds one-to-one to the plurality of switches SW51 to SW54, and each of the plurality of capacitors CA31 to CA34 is connected in series to a corresponding switch of the plurality of switches SW51 to SW54. The capacitance of the variable capacitor VC3 is varied by switching ON/OFF of each of the plurality of switches SW51 to SW54.

The filter circuit 40 forms a low pass filter. This configuration enables the filter circuit 40 to reduce the radio frequency components contained in the power supply voltage Vcc. For example, when a predetermined band is a frequency band for frequency division duplex (FDD), the filter circuit 40 is configured to reduce components of the downlink operation band of the predetermined band.

The filter characteristics of the filter circuit 40 of Exemplary Embodiment 8 have the one attenuation pole. The frequency of the one attenuation pole is determined by the circuit constant of each of the inductor L3 and the variable capacitor VC3 of the LC series circuit 43.

Similarly to the filter circuit 40 of Exemplary Embodiment 3, the filter circuit 40 of Exemplary Embodiment 8 reduces the amplitude of the spike-like voltage of an output voltage output from the supply modulator 30. That is, by including the filter circuit 40, the power supply circuit 1 can reduce waveform distortion in an output voltage output from the supply modulator 30, so that the power supply circuit 1 can reduce high frequency components in the output voltage described above. This configuration reduces noise contained in the power supply voltage Vcc in the power supply circuit 1, so that noise entering the power amplifier 2 from the power supply circuit 1 is also reduced.

In the tracker module 100 according to Exemplary Embodiment 8, the variable capacitor VC3 of the filter circuit 40 is integrated in the IC chip 80. In the IC chip 80, in a plan view of the thickness direction DO of the IC chip 80, the BS switch portion 105 in which the plurality of switches S81 to S84 of the band select switch circuit 50 is formed is adjacent to the functional element portion 106 in which the variable capacitor VC3 of the filter circuit 40 is formed.

In addition, in the tracker module 100 according to Exemplary Embodiment 8, the inductor L0 and the inductor L1 of the filter circuit 40 are disposed on the module laminate 9. More specifically, the inductor L0 and the inductor L1 are disposed on the first principal surface 91 of the module laminate 9. Each of the inductor L0 and the inductor L1 is a chip inductor. That is, each of the inductor L0 and the inductor L1 is a surface-mount type inductor.

### (2) Technical Effects

In the tracker module 100 according to Exemplary Embodiment 8, similarly to Exemplary Embodiment 7, the variable capacitor VC3 is connected to the supply modulator 30, and the inductor L3 is connected between the variable capacitor VC3 and ground. This can simplify wiring between the inside of the IC chip 80 and the outside of the IC chip 80.

### (3) Modification Example of Exemplary Embodiment 8

In the following, a modification example of Exemplary Embodiment 8 will be described.

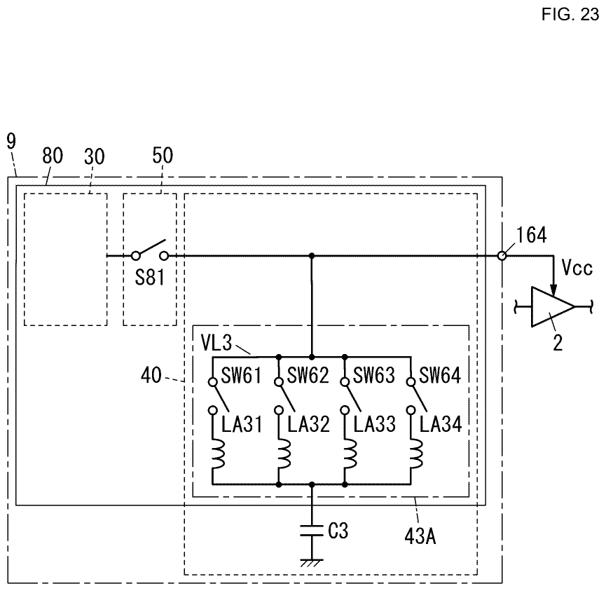

The tracker module 100 according to the modification example of Exemplary Embodiment 8 differs from the tracker module 100 according to Exemplary Embodiment 8 (see, e.g., FIG. 22) in that as illustrated in FIG. 23, the filter circuit 40 has the LC series circuit 43A instead of the LC series circuit 43.

The LC series circuit 43A includes a capacitor C3 and a variable inductor VL3. The capacitor C3 and the variable inductor VL3 are connected in series between the one end of the inductor L0 and ground. More specifically, the one end (first end) of the variable inductor VL3 is connected to the one end (first end) of the inductor L0, the other end (second end) of the variable inductor VL3 is connected to the one of the two electrodes of the capacitor C3, and the other electrode of the two electrodes of the capacitor C3 is connected to ground.

The variable inductor VL3 includes the plurality of (four in the example of FIG. 23) inductors LA31 to LA34 and the plurality of switches SW61 to SW64. The plurality of inductors LA31 to LA34 corresponds one-to-one to the plurality of switches SW61 to SW64, and each of the plurality of inductors LA31 to LA34 is connected in series to the corresponding switch of the plurality of switches SW61 to SW64. The inductance of the variable inductor VL3 is varied by switching ON/OFF each of the plurality of switches SW61 to SW64.

In the tracker module 100 according to the modification example of Exemplary Embodiment 8, the variable inductor VL3 of the filter circuit 40 is integrated in the IC chip 80. In the IC chip 80, in a plan view of the thickness direction DO of the IC chip 80, the BS switch portion 105 in which the plurality of switches S81 to S84 of the band select switch circuit 50 is formed is adjacent to the functional element portion 106 in which the variable inductor VL3 of the filter circuit 40 is formed.

In addition, in the tracker module 100 according to the modification example of Exemplary Embodiment 8, although not illustrated, the inductor L0 and the capacitor C3 of the filter circuit 40 are disposed on the module laminate 9. More specifically, the inductor L0 and the capacitor C3 are disposed on the first principal surface 91 of the module laminate 9. The inductor L0 is a chip inductor, and the capacitor C3 is a chip capacitor. That is, the inductor L0 is a surface-mount type inductor, and the capacitor C3 is a surface-mount type capacitor.

The tracker module 100 according to the modification example described above also produces similar effects to the tracker module 100 according to Exemplary Embodiment 8.

### Exemplary Embodiment 9

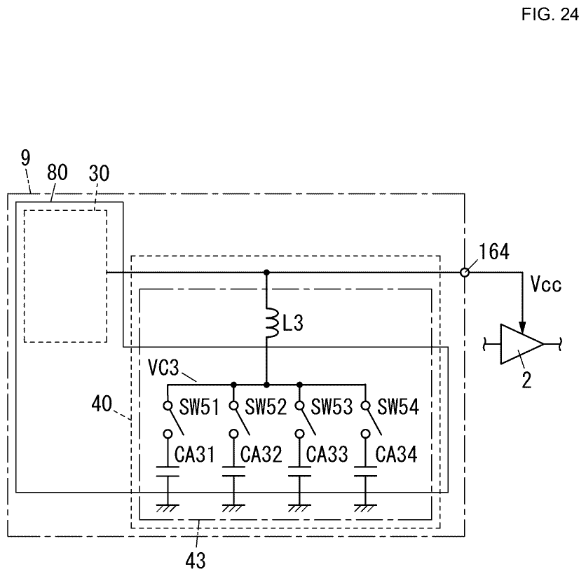

The tracker module 100 according to Exemplary Embodiment 9 differs from the tracker module 100 according to Exemplary Embodiment 2 (see, e.g., FIG. 9) in that as illustrated in FIG. 24, the filter circuit 40 is not adjacent to the supply modulator 30 and the band select switch circuit 50. For purposes of this disclosure, it is noted that for the tracker module 100 according to Exemplary Embodiment 9, components similar to those of the tracker module 100 according to Exemplary Embodiment 1 will be denoted by the same reference numerals and a description thereof will be omitted.

### Configuration

The tracker module 100 according to Exemplary Embodiment 9 does not include the band select switch circuit 50.

The filter circuit 40 according to Exemplary Embodiment 9 is not adjacent to the supply modulator 30 in a plan view of the thickness direction DO of the module laminate 9 in the IC chip 80. In addition, the filter circuit 40 is not adjacent to the band select switch circuit 50 either, because the band select switch circuit 50 is not provided.

### (2) Technical Effects

In the tracker module 100 according to Exemplary Embodiment 9 as well, similarly to Exemplary Embodiment 2, the size of the tracker module 100 can be reduced compared to a case in which the switches SW51 to SW54 of the variable capacitor VC3 are not integrated in the IC chip 80.

### (3) Modification Example of Exemplary Embodiment 9

In the following, a modification example of Exemplary Embodiment 9 will be described.

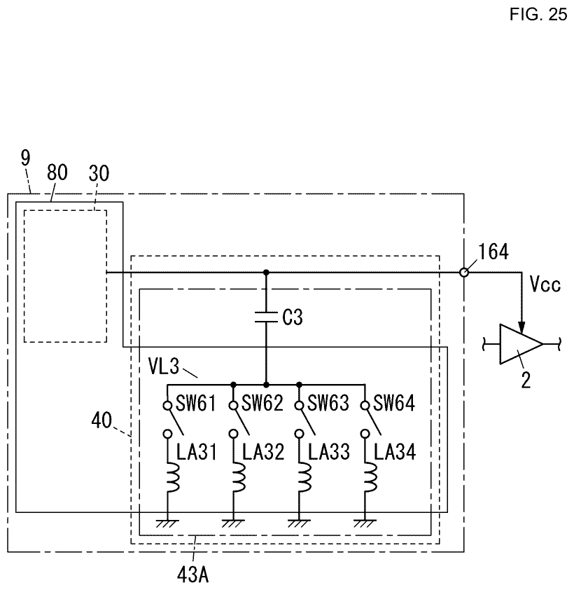

The tracker module 100 according to the modification example of Exemplary Embodiment 9 differs from the tracker module 100 according to Exemplary Embodiment 9 (see, e.g., FIG. 24) in that as illustrated in FIG. 25, the filter circuit 40 has the LC series circuit 43A instead of the LC series circuit 43.

The tracker module 100 according to the modification example described above also produces similar effects to the tracker module 100 according to Exemplary Embodiment 9.

It is generally noted that the embodiments and modification examples described above are merely a part of the various embodiments and modifications of the present disclosure. In addition, various changes can be made to the embodiments and modification examples depending on a design, and the like, as would be appreciated to one skilled in the art.

The following exemplary aspects are disclosed herein.

The tracker module (100) according to first exemplary aspect includes a module laminate (9), an IC chip (80), and a filter circuit (40). The IC chip (80) is disposed on the module laminate (9). The IC chip (80) includes at least one switch (S51 to S54) included in a supply modulator (30). The supply modulator (30) is configured to selectively output, to a power amplifier (2), at least one of a plurality of discrete voltages generated based on an input voltage with the filter circuit (40) interposed therebetween. The filter circuit (40) includes variable reactance elements (variable capacitors VC1 to VC3; variable inductors VL1 to VL3). The variable reactance elements include at least one reactance element (capacitors CA11 to CA14, CA21 to CA24, and CA31 to CA34; inductors LA11 to LA14, LA21 to LA24, and LA 31 to LA34), which can be a capacitor or an inductor, and at least one switch (SW11 to SW14, SW21 to SW24, and SW51 to SW54; SW31 to SW34, SW41 to SW44, and SW61 to SW64). The at least one switch (SW11 to SW14, SW21 to SW24, and SW51 to SW54; SW31 to SW34, SW41 to SW44, and SW61 to SW64) of the variable reactance elements in the filter circuit (40) is integrated in the IC chip (80).

According to the tracker module (100) according to the first exemplary aspect, a size of the tracker module 100 can be reduced as compared to a case in which the switches (SW11 to SW14, SW21 to SW24, and SW51 to SW54; SW31 to SW34, SW41 to SW44, and SW61 to SW64) of the variable reactance elements (variable capacitors VC1 to VC3; variable inductors VL1 to VL3) in the filter circuit (40) are not integrated in the IC chip (80).

A tracker module (100) according to a second exemplary aspect includes a module laminate (9), an IC chip (80), and a filter circuit (40). The IC chip (80) is disposed on the module laminate (9). The IC chip (80) includes at least one switch (S11 to S14, S21 to S24, S31 to S34, and S41 to S44) included in a switched-capacitor circuit (20) and at least one switch (S51 to S54) included in a supply modulator (30). The switched-capacitor circuit (20) includes a first capacitor (capacitor C12) having a first electrode and a second electrode, and a second capacitor (capacitor C15) having a third electrode and a fourth electrode. The at least one switch (S11 to S14, S21 to S24, S31 to S34, and S41 to S44) included in the switched-capacitor circuit (20) includes a first switch (switch S21), a second switch (switch S32), a third switch (switch S22), a fourth switch (switch S31), a fifth switch (switch S23), a sixth switch (switch S34), a seventh switch (switch S24), and an eighth switch (switch S33). A first end of the first switch and a first end of the third switch are connected to the first electrode of the first capacitor. A first end of the second switch and a first end of the fourth switch are connected to the second electrode of the first capacitor. A first end of the fifth switch and a first end of the seventh switch are connected to the third electrode of the second capacitor. A first end of the sixth switch and a first end of the eighth switch are connected to the fourth electrode of the second capacitor. A second end of the first switch, a second end of the second switch, a second end of the fifth switch, and a second end of the sixth switch are connected to each other. A second end of the third switch is connected to a second end of the seventh switch. A second end of the fourth switch is connected to a second end of the eighth switch. The at least one switch (S51 to S54) included in the supply modulator (30) includes a ninth switch (switch S53), which is connected between the second end of the first switch, the second end of the second switch, the second end of the fifth switch, the second end of the sixth switch, and the filter circuit (40), and a tenth switch (switch S52) which is connected between the second end of the third switch, the second end of the seventh switch, and the filter circuit (40). The filter circuit (40) includes variable reactance elements (variable capacitors VC1 to VC3; variable inductors VL1 to VL3). The variable reactance elements include at least one reactance element (capacitors CA11 to CA14, CA21 to CA24, and CA31 to CA34; inductors LA11 to LA14, LA21 to LA24, and LA 31 to LA34), which can be a capacitor or an inductor, and at least one switch (SW11 to SW14, SW21 to SW24, and SW51 to SW54; SW31 to SW34, SW41 to SW44, and SW61 to SW64) corresponding to the at least one reactance element. The at least one reactance element includes a first reactance element and a second reactance element which is connected in parallel to the first reactance element. The at least one switch of the filter circuit (40) includes an eleventh switch which is connected in series to the first reactance element, and a twelfth switch which is connected in parallel to the eleventh switch and is connected in series to the second reactance element. The at least one switch (SW11 to SW14, SW21 to SW24, and SW51 to SW54; SW31 to SW34, SW41 to SW44, and SW61 to SW64) of the variable reactance elements in the filter circuit (40) is integrated in the IC chip (80).

According to the tracker module (100) according to the second exemplary aspect, the size of the tracker module 100 can be reduced as compared to a case in which the switches (SW11 to SW14, SW21 to SW24, and SW51 to SW54; SW31 to SW34, SW41 to SW44, and SW61 to SW64) of the variable reactance elements (variable capacitors VC1 to VC3; variable inductors VL1 to VL3) in the filter circuit (40) are not integrated in the IC chip (80).

In a tracker module (100) according to a third exemplary aspect, in the first aspect, the IC chip (80) further includes at least one switch (S11 to S14, S21 to S24, S31 to S34, and S41 to S44) included in a switched-capacitor circuit (20). The switched-capacitor circuit (20) is configured to generate the plurality of discrete voltages based on the input voltage.

According to the tracker module (100) according to the third exemplary aspect, the size can be reduced as compared to a case in which the switches (S11 to S14, S21 to S24, S31 to S34, and S41 to S44) of the switched-capacitor circuit (20) are not provided in the IC chip 80.

In a tracker module (100) according to a fourth exemplary aspect, in the second or third aspect, the at least one switch (SW11 to SW14, SW21 to SW24, SW51 to SW54; SW31 to SW34, SW41 to SW44, SW61 to SW64) of the variable reactance elements (variable capacitors VC1 to VC3; variable inductors VL1 to VL3) in the filter circuit (40) is separated from the at least one switch (S11 to S14, S21 to S24, S31 to S34, and S41 to S44) included in the switched-capacitor circuit (20) in a plan view of a thickness direction (DO) of the module laminate (9).

According to the tracker module (100) according to the fourth exemplary aspect, the switches (SW11 to SW14, SW21 to SW24, SW51 to SW54; SW31 to SW34, SW41 to SW44, SW61 to SW64) of the variable reactance elements (variable capacitors VC1 to VC3; variable inductors VL1 to VL3) in the filter circuit (40) can be separated from the switches (S11 to S14, S21 to S24, S31 to S34, and S41 to S44) of the switched-capacitor circuit 20 which are prone to generate heat. Therefore, in the filter circuit 40, influence of heat from the switches (S11 to S14, S21 to S24, S31 to S34, and S41 to S44) of the switched-capacitor circuit (20) is reduced.

In a tracker module (100) according to a fifth exemplary aspect, in any one of the second to fourth aspects, the at least one reactance element (capacitors CA11 to CA14, CA21 to CA24, and CA31 to CA34; inductors LA11 to LA14, LA21 to LA24, and LA 31 to LA34) of the variable reactance elements (variable capacitors VC1 to VC3; variable inductors VL1 to VL3) in the filter circuit (40) further includes a third reactance element which is connected in parallel to the first reactance element and the second reactance element. The first reactance element and the second reactance element are capacitors. The third reactance element is an inductor.

In a tracker module (100) according to a sixth exemplary aspect, in any one of the second to fourth aspects, the at least one reactance element (capacitors CA11 to CA14, CA21 to CA24, and CA31 to CA34; inductors LA11 to LA14, LA21 to LA24, and LA 31 to LA34) of the variable reactance elements (variable capacitors VC1 to VC3; variable inductors VL1 to VL3) in the filter circuit (40) further includes a third reactance element which is connected in parallel to the first reactance element and the second reactance element. The first reactance element and the second reactance element are inductors. The third reactance element is a capacitor.

In a tracker module (100) according to a seventh exemplary aspect, in any one of the first to sixth aspects, the at least one reactance element (capacitors CA11 to CA14, CA21 to CA24, and CA31 to CA34; inductors LA11 to LA14, LA21 to LA24, and LA 31 to LA34) of the variable reactance elements (variable capacitors VC1 to VC3; variable inductors VL1 to VL3) in the filter circuit (40) is integrated in the IC chip (80).

According to a tracker module (100) according to a seventh exemplary aspect, the size can be reduced as compared to a case in which reactance elements (capacitors CA11 to CA14, CA21 to CA24, and CA31 to CA34; inductors LA11 to LA14, LA21 to LA24, and LA 31 to LA34) in a filter circuit (40) are not integrated in an IC chip (80).

In a tracker module (100) according to an eighth exemplary aspect, in any one of the first to seventh aspects, the IC chip (80) further includes a plurality of switches (S81 to S84) included in a band select switch circuit (50). The at least one switch (SW11 to SW14, SW21 to SW24, SW51 to SW54; SW31 to SW34, SW41 to SW44, SW61 to SW64) of the variable reactance elements (variable capacitors VC1 to VC3; variable inductors VL1 to VL3) in the filter circuit (40) is adjacent to the plurality of switches (S81 to S84) of the band select switch circuit (50), in a plan view of a thickness direction (DO) of the module laminate (9).

According to the tracker module (100) according to the eighth exemplary aspect, a wiring length between the band select switch circuit (50) and the filter circuit (40) can also be shortened.

In the tracker module (100) according to a ninth aspect, in any one of the first to eighth exemplary aspect, the at least one switch (SW11 to SW14, SW21 to SW24, SW51 to SW54; SW31 to SW34, SW41 to SW44, SW61 to SW64) of the variable reactance elements (variable capacitors VC1 to VC3; variable inductors VL1 to VL3) in the filter circuit (40) is adjacent to the at least one switch (S51 to S54) of the supply modulator (30), in a plan view of the thickness direction (DO) of the module laminate (9).

According to the tracker module (100) according to the ninth exemplary aspect, a wiring length between the supply modulator (30) and the filter circuit (40) can also be shortened.

In a tracker module (100) according to a tenth exemplary aspect, in any one of the first to fourth aspects, the filter circuit (40) further includes inductors (L1; L2; L3). The variable reactance elements of the filter circuit (40) are connected in series to the inductors, and include variable capacitors (VC1; VC2; VC3) whose capacitance is varied.

In a tracker module (100) according to an eleventh exemplary aspect, in the tenth aspect, the variable capacitors (VC1; VC2; VC3) of the filter circuit (40) are connected to the supply modulator (30). The inductors (L1; L2; L3) of the filter circuit (40) are connected between the variable capacitors (VC1; VC2; VC3) and ground.

According to the tracker module (100) according to the eleventh exemplary aspect, wiring between the inside of the IC chip (80) and the outside of the IC chip (80) can be simplified.

In a tracker module (100) according to a twelfth exemplary aspect, in the tenth aspect, the inductors (L1; L2; L3) of the filter circuit (40) are connected to the supply modulator (30). The variable capacitors (VC1; VC2; VC3) of the filter circuit (40) are connected between the inductors (L1; L2; L3) and ground.

In a tracker module (100) according to a thirteenth exemplary aspect, in any one of the first to fourth aspects, the filter circuit (40) further includes capacitors (C1; C2; C3). The variable reactance elements of the filter circuit (40) are connected in series to the capacitors (C1; C2; C3), and include variable inductors (VL1; VL2; VL3) whose inductance is varied.

In a tracker module (100) according to a fourteenth exemplary aspect, in the thirteenth aspect, the variable inductors (VL1; VL2; VL3) of the filter circuit (40) are connected to the supply modulator (30). The capacitors (C1; C2; C3) of the filter circuit (40) are connected between the variable inductors (VL1; VL2; VL3) and ground.

According to the tracker module (100) according to the fourteenth exemplary aspect, wiring between the inside of the IC chip (80) and the outside of the IC chip (80) can be simplified.

In a tracker module (100) according to a fifteenth exemplary aspect, in the thirteenth aspect, the capacitors (C1; C2) of the filter circuit (40) are connected to the supply modulator (30). The variable inductors (VL1; VL2; VL3) of the filter circuit (40) are connected between the capacitors (C1; C2; C3) and ground.

A tracker module (100) according to a sixteen exemplary aspect, in any one of the first to fifteenth aspects, further includes an output terminal (164). The output terminal (164) is disposed on the module laminate (9), and is connected to the supply modulator (30) with the filter circuit (40) interposed therebetween. The filter circuit (40) has first LC series circuits (41; 41A) and second LC series circuits (42; 42A). The first LC series circuits (41; 41A) are connected between a path, which connects the supply modulator (30) and the output terminal (164), and ground. The second LC series circuits (42; 42A) are connected between the path, which connects the supply modulator (30) and the output terminal (164), and ground.

According to the tracker module (100) according to the sixteenth exemplary aspect, harmonic waves can also be reduced.

In a tracker module (100) according to a seventeenth exemplary aspect, in the sixteenth aspect, the filter circuit (40) further includes a first changeover switch (SW1) and a second changeover switch (SW2). The first changeover switch (SW1) is connected in series to the first LC series circuits (41; 41A) between the path and the ground. The second changeover switch (SW2) is connected in series to the second LC series circuits (42; 42A) between the path and the ground. The first changeover switch (SW1) and the second changeover switch (SW2) are integrated in the IC chip (80).

According to the tracker module (100) according to the seventeenth exemplary aspect, it is possible to change attenuation poles in filter characteristics of the filter circuit (40).

A high frequency system (200) according to an eighteenth exemplary aspect includes the tracker module (100) of any one of the first to seventeenth aspects, and a power amplifier (2). The power amplifier (2) is connected to the tracker module (100).

According to the high frequency system (200) according to the eighteenth exemplary aspect, in the tracker module (100), a size can be reduced as compared to a case in which switches (SW11 to SW14, SW21 to SW24, and SW51 to SW54; SW31 to SW34, SW41 to SW44, and SW61 to SW64) of variable reactance elements (variable capacitors VC1 to V C3; variable inductors VL1 to VL3) are not integrated in an IC chip 80.

A communication device (7) according to a nineteenth exemplary aspect includes the high frequency system (200) according to the eighteenth aspect and a signal processing circuit (5). The signal processing circuit (5) is connected to the high frequency system (200).

According to the communication device (7) according to the nineteenth exemplary aspect, in a tracker module (100) provided in the high frequency system (200), a size can be reduced as compared to a case in which switches (SW11 to SW14, SW21 to SW24, and SW51 to SW54; SW31 to SW34, SW41 to SW44, and SW61 to SW64) of variable reactance elements (variable capacitors VC1 to V C3; variable inductors VL1 to VL3) are not integrated in an IC chip 80.

### REFERENCE SIGNS LIST

1 power supply circuit
2 power Amplifier
3 filter
4 control circuit
5 signal processing circuit
51 RF signal processing circuit
52 baseband signal processing circuit
511 control unit
6 antenna
7 communication device
10 pre-regulator circuit
20 switched-capacitor circuit
30 supply modulator
40 filter circuit
41, 41A first LC series circuit
42, 42A second LC series circuit
43, 43A LC series circuit
50 band select switch circuit
60 digital control circuit
61 first controller
62 second controller
601, 602, 603, 604 control terminal
70 direct current (DC) power source
80 IC chip
81 input/output electrode
800 outer edge
801 first side
802 second side
803 third side
804 fourth side
9 module laminate
91 first principal surface
92 second principal surface
93 outer peripheral surface
94 resin layer
941 principal surface
943 outer peripheral surface
95 shield electrode layer
100 tracker module
101 PR switch portion
102 SC switch portion
103 SC switch portion
104 SM switch portion
105 BS switch portion
106 functional element portion
107 digital control unit
110, 131, 132, 133, 134, 141 input terminal
111, 112, 113, 114, 130, 142 output terminal
115, 116 inductor connection terminal
117, 120, 135 control terminal
150 common terminal
151, 152, 153, 154 selection terminal
155 control terminal
160 external connection terminal
161 input terminal
164 output terminal
165 input control terminal
200 high frequency system
C1, C2, C3 capacitor
C11, C12, C13, C14, C15, C16 capacitor
C21, C22, C23, C24 capacitor
C61, C62, C63, C64 capacitor
C81, C82 capacitor
CA11, CA12, CA13, CA14 capacitor (reactance elements)
CA21, CA22, CA23, CA24 capacitor (reactance elements)
CA31, CA32, CA33, CA34 capacitor (reactance elements)
L0, L1, L2, L3 inductor
L71 power inductor
LA11, LA12, LA13, LA14 inductor (reactance element)
LA21, LA22, LA23, LA24 inductor (reactance element)
LA31, LA32, LA33, LA34 inductor (reactance element)
VC1, VC2, VC3 variable capacitor (variable reactance element)
VL1, VL2, VL3 variable inductor (variable reactance element)
S11, S12, S13, S14 switch
S21, S22, S23, S24 switch
S31, S32, S33, S34 switch
S41, S42, S43, S44 switch
S51, S52, S53, S54 switch
S61, S62, S63 switch
S71, S72 switch
S81, S82, S83, S84 switch
Sg1, Sg2, Sg3, Sg4 control signal
Sg7 clock signal
Sg8 data signal
SW1 first changeover switch
SW2 second changeover switch
SW3 changeover switch
SW11, SW12, SW13, SW14 switch
SW21, SW22, SW23, SW24 switch
SW31, SW32, SW33, SW34 switch
SW41, SW42, SW43, SW44 switch
SW51, SW52, SW53, SW54 switch
SW61, SW62, SW63, SW64 switch
T1 antenna terminal
T2 signal input terminal
T3 first control terminal
T4 power connection terminal
T5 second control terminal
V1, V2, V3, V4 voltage
Vcc power supply voltage
DCL1, DCL2 digitally-controlled level signal
N1, N2, N3, N4 nodes
DO thickness direction

1. A tracker module comprising:
a module laminate;
a filter circuit that includes variable reactance elements; and
an IC chip disposed on the module laminate and that at least one switch included in a supply modulator that is configured to selectively output, to a power amplifier, at least one discrete voltage of a plurality of discrete voltages generated based on an input voltage,
wherein the filter circuit interposed between the power amplifier and the at least one switch,
wherein the variable reactance elements include at least one reactance element, and at least one switch, and
wherein the at least one switch of the variable reactance elements in the filter circuit is integrated in the IC chip.

2. The tracker module according to claim 1, wherein the IC chip further includes at least one switch included in a switched-capacitor circuit that is configured to generate the plurality of discrete voltages based on the input voltage.

3. The tracker module according to claim 2, wherein the at least one switch of the variable reactance elements in the filter circuit is separated from the at least one switch of the switched-capacitor circuit in a plan view in a thickness direction of the module laminate.

4. The tracker module according to claim 1, wherein the at least one reactance element of the variable reactance elements in the filter circuit is integrated in the IC chip.

5. The tracker module according to claim 1, wherein:
the IC chip further includes a band select switch circuit that comprises a plurality of switches, and
the at least one switch of the variable reactance elements in the filter circuit is adjacent to the plurality of switches of the band select switch circuit in a plan view in the thickness direction of the module laminate.

6. The tracker module according to claim 1, wherein the at least one switch of the variable reactance elements in the filter circuit is adjacent to the at least one switch of the supply modulator in a plan view in the thickness direction of the module laminate.

7. The tracker module according to claim 1, wherein:
the filter circuit further includes a plurality of inductors, and
the variable reactance elements of the filter circuit are connected in series to the plurality of inductors and include a plurality of variable capacitors.

8. The tracker module according to claim 7, wherein:
the plurality of variable capacitors of the filter circuit are connected to the supply modulator, and
the plurality of inductors of the filter circuit are connected between the plurality of variable capacitors and a ground connection.

9. The tracker module according to claim 7, wherein:
the plurality of inductors of the filter circuit are connected to the supply modulator, and
the plurality of variable capacitors of the filter circuit are connected between the plurality of inductors and a ground connection.

10. The tracker module according to claim 1, wherein:
the filter circuit further includes a plurality of capacitors, and
the variable reactance elements of the filter circuit are connected in series to the plurality of capacitors and include a plurality of variable inductors.

11. The tracker module according to claim 10, wherein:
the plurality of variable inductors of the filter circuit are connected to the supply modulator,
the plurality of capacitors of the filter circuit are connected between the plurality of variable inductors and a ground connection.

12. The tracker module according to claim 10, wherein:
the plurality of capacitors of the filter circuit are connected to the supply modulator, and
the plurality of variable inductors of the filter circuit are connected between the plurality of capacitors and a ground connection.

13. The tracker module according to claim 1, further comprising:
an output terminal that is disposed on the module laminate and the is connected to the supply modulator with the filter circuit interposed therebetween,
wherein the filter circuit includes:
at least one first LC series circuit connected between a ground connection and a path that connects the supply modulator to the output terminal; and
at least one second LC series circuit connected between the ground connection and the path that connects the supply modulator to the output terminal.

14. The tracker module according to claim 13, wherein:
the filter circuit further includes:
a first changeover switch connected in series to the at least one first LC series circuit between the path and the ground connection; and
a second changeover switch connected in series to the at least one second LC series circuits between the path and the ground connection, and
the first changeover switch and the second changeover switch are integrated in the IC chip.

15. A high frequency system comprising:
the tracker module according to claim 1, and
a power amplifier connected to the tracker module.

16. A communication device comprising:
the high frequency system according to claim 15; and
a signal processing circuit connected to the high frequency system.

17. A tracker module comprising:
a module laminate;
a filter circuit; and
an IC chip disposed on the module laminate and including:
at least one switch included in a switched-capacitor circuit that includes:
a first capacitor having a first electrode and a second electrode, and
a second capacitor having a third electrode and a fourth electrode,
and
at least one switch included in a supply modulator,
wherein the at least one switch included in the switched-capacitor circuit includes:
a first switch, a second switch, a third switch, a fourth switch, a fifth switch, a sixth switch, a seventh switch, and an eighth switch,
wherein:
a first end of the first switch and a first end of the third switch are connected to the first electrode of the first capacitor,
a first end of the second switch and a first end of the fourth switch are connected to the second electrode of the first capacitor,
a first end of the fifth switch and a first end of the seventh switch are connected to the third electrode of the second capacitor,
a first end of the sixth switch and a first end of the eighth switch are connected to the fourth electrode of the second capacitor,
a second end of the first switch, a second end of the second switch, a second end of the fifth switch, and a second end of the sixth switch are connected to each other,
a second end of the third switch is connected to a second end of the seventh switch, and
a second end of the fourth switch is connected to a second end of the eighth switch,
wherein the at least one switch included in the supply modulator includes:
a ninth switch that is connected between the second end of the first switch, the second end of the second switch, the second end of the fifth switch, the second end of the sixth switch, and the filter circuit, and
a tenth switch that is connected between the second end of the third switch, the second end of the seventh switch, and the filter circuit,
wherein the filter circuit includes variable reactance elements that include:
at least one reactance element that is a capacitor or an inductor, and
at least one switch corresponding to the at least one reactance element, wherein the at least one reactance element includes:
a first reactance element; and
a second reactance element that is connected in parallel to the first reactance element,
wherein the at least one switch of the filter circuit includes:
an eleventh switch that is connected in series to the first reactance element, and
a twelfth switch that is connected in parallel to the eleventh switch and is connected in series to the second reactance element, and
wherein the at least one switch of the variable reactance elements in the filter circuit is integrated in the IC chip.

18. The tracker module according to claim 17, wherein the at least one switch of the variable reactance elements in the filter circuit is separated from the at least one switch of the switched-capacitor circuit in a plan view of a thickness direction of the module laminate.

19. The tracker module according to claim 17, wherein:
the at least one reactance element of the variable reactance elements in the filter circuit further includes a third reactance element that is connected in parallel to the first reactance element and the second reactance element,
the first reactance element and the second reactance element are capacitors, and
the third reactance element is an inductor.

20. The tracker module according to claim 17, wherein:
the at least one reactance element of the variable reactance elements in the filter circuit further includes a third reactance element that is connected in parallel to the first reactance element and the second reactance element,
the first reactance element and the second reactance element are inductors, and
the third reactance element is a capacitor.
